(19) United States
(12) Patent Application Publication
(10) Pub. No.: US 2014/0306586 A1
(43) Pub. Date: Oct. 16, 2014

(54) SYSTEMS AND METHODS FOR PROVIDING MODULAR PACKAGING

(71) Applicant: Jason A. Sullivan, Salt Lake City, UT (US)

(72) Inventor: Jason A. Sullivan, Salt Lake City, UT (US)

(21) Appl. No.: 14/147,530

(22) Filed: Jan. 4, 2014

Related U.S. Application Data
(60) Provisional application No. 61/749,851, filed on Jan. 7, 2013.

(51) Int. Cl. G06F 1/18; H05K 5/02; H05K 5/00

(52) U.S. Cl. CPC G06F 1/181; H05K 5/0004; H05K 5/0239
USPC 312/223.2

(57) ABSTRACT

Systems and methods for providing modular packaging that includes a base that is configured to receive any of a number of tops or lids, wherein the particular top or lid used in association with the base is determined based upon the volume needed within the overall packaging to contain, support and protect the contents inside the packaging. In at least some implementations, the lid or top is configured to cover the item to be packaged and mate with the base to form an enclosure. The base includes a bottom portion and a top portion such that the combination forms a cavity for inclusion of other items to be packaged along with the item that is enclosed within the top or lid. The top portion of the base provides a mounting platform with a connector. An outer skin or covering is provided over the top and base combination.

### CROSS-REFERENCE TO RELATED APPLICATION

This application claims priority to U.S. Provisional Patent Application Ser. No. 61/749,851, filed Jan. 7, 2013, entitled “SYSTEMS AND METHODS FOR PROVIDING MODULAR PACKAGING”, the entire disclosure of which is expressly incorporated herein by reference for all it discloses.

### BACKGROUND OF THE INVENTION

1. Field of the Invention

The present invention relates to dynamically modular packaging. More particularly, embodiments of the present invention relate to systems and methods for providing modular packaging, including modular packaging for computer systems, devices, and components.

2. Background and Related Art

Existing devices such as storage devices traditionally utilize a single bus system (e.g. PATA, SATA, PCIe, etc.) and are typically limited to a single medium (e.g. a spinning disk or a solid-state storage medium). These devices may be available in different storage sizes and/or capabilities, and different physical sizes and/or form factors. Currently, the choice of medium is commonly determined by balancing a variety of factors such as a desired speed of access, size of storage and physical size, and also cost.

The considerations involved in selecting among the available devices are further constrained in the context of selecting among external devices such as external storage systems. Such systems are commonly connected to a central computer device by an external cable (e.g. USB, IEEE 1394 (Firewire), PCIe, eSATA, etc.) and are often constrained or limited to a single device or function. The size constraints of such devices may be even more strict than the size constraints discussed above.

Many devices utilize a printed circuit board (PCB) or other functional and/or structural board to provide certain mounting functions. In such devices, it is normal for components of the device to be mounted exclusively on a single side of the PCB or other board.

The limitations of existing systems as described above contribute to some of the difficulties described in the related applications.

### BRIEF SUMMARY OF THE INVENTION

Implementation of various embodiments of the present invention relates to systems and methods for providing modular packaging. In particular, at least some implementations relate to modular packaging of modular computing systems, devices, and/or components.

In some implementations, modular packaging is provided for a modular computer device having a housing defining an internal volume. A printed circuit board is mounted within the housing. The printed circuit board has a first major surface and an opposite second major surface, and a first computing component is communicatively connected to the printed circuit board and disposed along the first major surface. The printed circuit board is configured to receive a second computing component communicatively connected to the printed circuit board and disposed along the second major surface, and, optionally, a second computing component is communicatively connected to the printed circuit board and disposed along the second major surface.

In at least some implementations, the modular packaging includes a base that is configured to receive any of a number of tops or lids, wherein the particular top or lid used in association with the base is determined based upon the volume needed within the overall packaging to contain, support and protect the contents inside the packaging. In at least some implementations, the base includes a bottom portion and a top portion. The combination of the top and bottom base portions forms a cavity for inclusion, for example, of components, connectors, cables, manuals, materials, and other items that are able to be packaged along with the computer device or other item that is being provided by the modular packaging. The top portion of the base provides a mounting platform with a connector system to selectively mount the computer device or other item being packaged. The lid or top is configured to cover the computer device or item to be packaged and mate with the base to form an enclosure. In some implementations, an outer skin or covering is provided over the top and base combination.

In at least some implementations, one or more surfaces of the top/lid and/or base are formed so as to limit movement of the contents inside of the packaging to increase stability and to further protect the contents. In some implementations, the top/lid includes one or more indents formed to touch or otherwise reside near a surface of the contents. In some implementations, at least a portion of the contents is imprinted on at least a portion of the top/lid to provide a location for contents. In some implementations, hangers and/or handles are provided for anti-theft devices. In some implementations, a lighting system is incorporated with the packaging to selectively provide illumination.

These and other features and advantages of the present invention will be set forth or will become more fully apparent in the description that follows and in the appended claims. The features and advantages may be realized and obtained by means of the instruments and combinations particularly pointed out in the appended claims. Furthermore, the features and advantages of the invention may be learned by the practice of the invention or will be obvious from the description, as set forth hereinafter.

### BRIEF DESCRIPTION OF THE SEVERAL VIEWS OF THE DRAWINGS

The objects and features of the present invention will become more fully apparent from the following description and appended claims, taken in conjunction with the accompanying drawings. Understanding that these drawings depict only typical embodiments of the invention and are, therefore, not to be considered limiting of its scope, the invention will be described and explained with additional specificity and detail through the use of the accompanying drawings in which:

FIG. 1 shows a representation of a computer system that can be used in conjunction with embodiments of the invention;

FIG. 2 shows a representative networked computer system that can be used in conjunction with embodiments of the invention;

FIG. 3 shows various representative configurations of a modular device according to embodiments of the invention;

FIGS. 4-8 show various views of portions of a housing of a modular device according to embodiments of the invention;

FIGS. 9-11 show various perspective views of a representative printed circuit board in a housing according to embodiments of a modular device;

FIGS. 12-14 show views of a representative printed circuit board;

FIG. 15 shows a side view of a T-shaped connector disposed within a slot of a printed circuit board;

FIG. 16 illustrates a representative mobile system in accordance with embodiments of the invention;

FIGS. 17-23 show various views of modular packaging in accordance with a representative embodiment of the present invention;

FIGS. 24-43 show various views of modular packaging in accordance with another representative embodiment of the present invention; and

FIGS. 44-47 show various views of modular packaging in accordance with other representative embodiments of the present invention.

### DETAILED DESCRIPTION OF THE INVENTION

A description of embodiments of the present invention will now be given with reference to the Figures. It is expected that the present invention may take many other forms and shapes, hence the following disclosure is intended to be illustrative and not limiting, and the scope of the invention should be determined by reference to the appended claims.

Embodiments of the present invention relate to modular packaging. More particularly, at least some embodiments of the present invention relate to modular packaging of computer systems, devices and components.

A representative embodiment of a modular computing device includes a housing defining an internal volume. A printed circuit board is mounted within the housing. The printed circuit board has a first major surface and an opposite second major surface, and a first computing component is communicatively connected to the printed circuit board and disposed along the first major surface. The printed circuit board is configured to receive a second computing component communicatively connected to the printed circuit board and disposed along the second major surface, and, optionally, a second computing component is communicatively connected to the printed circuit board and disposed along the second major surface.

In accordance with at least some embodiments of the present invention, modular packaging is provided for use in association with computer systems, devices and/or components. Accordingly, a discussion will first be provided relating to representative computer systems, devices and/or components and followed by a discussion of representative modular packaging. The following portion of the description is broken into several headings for purposes of increasing understanding of the description, and is not intended to be limiting in any way.

### Representative Operating Environments

The following description of operating environments should be understood to be illustrative of the types of environments in which embodiments of the invention may be utilized and implemented, and it is not intended that all embodiments of the invention include every feature discussed herein or be utilized in environments containing every feature discussed herein. The following is therefore intended to assist in understanding the various embodiments of the invention only.

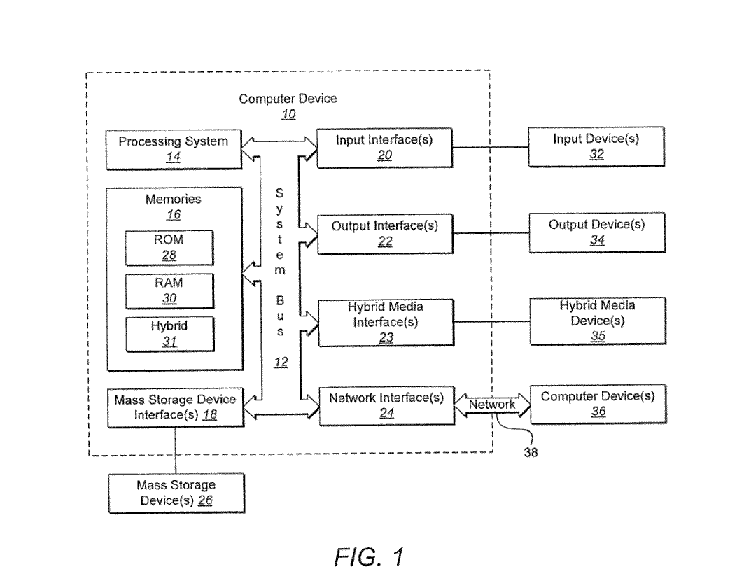

FIG. 1 and the corresponding discussion are intended to provide a general description of a suitable operating environment in which embodiments of the invention may be implemented, taken in conjunction with the disclosure of the related applications incorporated herein by reference. One skilled in the art will appreciate that embodiments of the invention may be practiced by one or more computing devices and in a variety of system configurations, including in a networked configuration. However, while the methods and processes of the present invention have proven to be particularly useful in association with a system comprising a general purpose computer, embodiments of the present invention include utilization of the methods and processes in a variety of environments, including embedded systems with general purpose processing units, digital/media signal processors (DSP/MSP), application specific integrated circuits (ASIC), stand alone electronic devices, and other such electronic environments.

Embodiments of the present invention embrace one or more computer-readable media, wherein each medium may be configured to include or includes thereon data or computer executable instructions for manipulating data. The computer executable instructions include data structures, objects, programs, routines, or other program modules that may be accessed by a processing system, such as one associated with a general-purpose computer capable of performing various different functions or one associated with a special-purpose computer capable of performing a limited number of functions. Computer executable instructions cause the processing system to perform a particular function or group of functions and are examples of program code means for implementing steps for methods disclosed herein. Furthermore, a particular sequence of the executable instructions provides an example of corresponding acts that may be used to implement such steps. Examples of computer-readable media include random-access memory (“RAM”), read-only memory (“ROM”), programmable read-only memory (“PROM”), erasable programmable read-only memory (“EPROM”), electrically erasable programmable read-only memory (“EEPROM”), compact disk read-only memory (“CD-ROM”), or any other device or component that is capable of providing data or executable instructions that may be accessed by a processing system. While embodiments of the invention embrace the use of all types of computer-readable media, certain embodiments as recited in the claims may be limited to the use of tangible, non-transitory computer-readable media, and the phrases “tangible computer-readable medium” and “non-transitory computer-readable medium” (or plural variations) used herein are intended to exclude transitory propagating signals per se.

With reference to FIG. 1, a representative system for implementing embodiments of the invention includes computer device 10, which may be a general-purpose or special-purpose computer or any of a variety of consumer electronic devices. For example, computer device 10 may be a personal computer, a notebook computer, a netbook, a personal digital assistant (“PDA”) or other hand-held device, a workstation, a minicomputer, a mainframe, a supercomputer, a multi-processor system, a network computer, a processor-based consumer electronic device, a modular computer as disclosed in the related applications or the like.

Computer device 10 includes system bus 12, which may be configured to connect various components thereof and enables data to be exchanged between two or more components. System bus 12 may include one of a variety of bus structures including a memory bus or memory controller, a peripheral bus, or a local bus that uses any of a variety of bus architectures. Typical components connected by system bus 12 include processing system 14 and memories 16. Other components may include one or more mass storage device interfaces 18, input interfaces 20, output interfaces 22, and/or network interfaces 24, each of which will be discussed below.

Processing system 14 includes one or more processors, such as a central processor and optionally one or more other processors designed to perform a particular function or task. It is typically processing system 14 that executes the instructions provided on computer-readable media, such as on memories 16, a magnetic hard disk, a removable magnetic disk, a magnetic cassette, an optical disk, or from a communication connection, which may also be viewed as a computer-readable medium.

Memories 16 includes one or more computer-readable media that may be configured to include or includes thereon data or instructions for manipulating data, and may be accessed by processing system 14 through system bus 12. Memories 16 may include, for example, ROM 28, used to permanently store information, RAM 30, used to temporarily store information, and/or hybrid memories 31. ROM 28 may include a basic input/output system (“BIOS”) having one or more routines that are used to establish communication, such as during start-up of computer device 10. RAM 30 may include one or more program modules, such as one or more operating systems, application programs, and/or program data. Hybrid memories 31 may have features and capabilities hybridized from those of ROM 28 and RAM 30.

One or more mass storage device interfaces 18 may be used to connect one or more mass storage devices 26 to system bus 12. The mass storage devices 26 may be incorporated into or may be peripheral to computer device 10 and allow computer device 10 to retain large amounts of data. Optionally, one or more of the mass storage devices 26 may be removable from computer device 10. Examples of mass storage devices include hard disk drives, magnetic disk drives, tape drives, solid state drives/flash drives, hybrid drives utilizing multiple storage types, and optical disk drives. A mass storage device 26 may read from and/or write to a magnetic hard disk, a removable magnetic disk, a magnetic cassette, an optical disk, or another computer-readable medium. Mass storage devices 26 and their corresponding computer-readable media provide nonvolatile storage of data and/or executable instructions that may include one or more program modules such as an operating system, one or more application programs, other program modules, or program data. Such executable instructions are examples of program code means for implementing steps for methods disclosed herein.

One or more input interfaces 20 may be employed to enable a user to enter data and/or instructions to computer device 10 through one or more corresponding input devices 32. Examples of such input devices include a keyboard and alternate input devices, such as a mouse, trackball, light pen, stylus, or other pointing device, a microphone, a joystick, a game pad, a satellite dish, a scanner, a camcorder, a digital camera, and the like. Similarly, examples of input interfaces 20 that may be used to connect the input devices 32 to the system bus 12 include a serial port, a parallel port, a game port, a universal serial bus (“USB”), an integrated circuit, a firewire (IEEE 1394), or another interface. For example, in some embodiments input interface 20 includes an application specific integrated circuit (ASIC) that is designed for a particular application. In a further embodiment, the ASIC is embedded and connects existing circuit building blocks.

One or more output interfaces 22 may be employed to connect one or more corresponding output devices 34 to system bus 12. Examples of output devices include a monitor or display screen, a speaker, a printer, a multi-functional peripheral, and the like. A particular output device 34 may be integrated with or peripheral to computer device 10. Examples of output interfaces include a video adapter, an audio adapter, a parallel port, and the like.

One or more hybrid media interfaces 23 may be employed to connect one or more hybrid media devices 35 to the system bus 12. A hybrid media interface 23 may include multiple single input/output ports and/or buses combined on a single connector to provide added value. Non-limiting examples of the types of ports/buses that can be combined in the hybrid media interface(s) 23 and/or associated buses/ports include PCIe, I²C, power, a proprietary secure bus, SATA, USB, and the like. The hybrid media devices 35 so connected to the computer device 10 may include a variety of peripheral devices, storage systems, PCIe devices, USB devices, SATA devices and the like.

One or more network interfaces 24 enable computer device 10 to exchange information with one or more other local or remote computer devices, illustrated as computer devices 36, via a network 38 that may include hardwired and/or wireless links. Examples of network interfaces include a network adapter for connection to a local area network (“LAN”) or a modem, wireless link, or other adapter for connection to a wide area network (“WAN”), such as the Internet. The network interface 24 may be incorporated with or peripheral to computer device 10. In a networked system, accessible program modules or portions thereof may be stored in a remote memory storage device. Furthermore, in a networked system computer device 10 may participate in a distributed computing environment, where functions or tasks are performed by a plurality of networked computer devices.

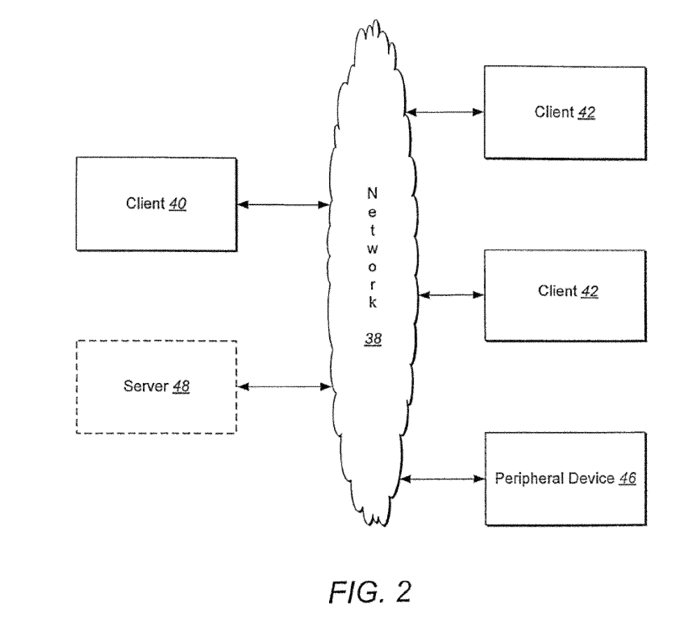

Thus, while those skilled in the art will appreciate that embodiments of the present invention may be practiced in a variety of different environments with many types of system configurations, FIG. 2 provides a representative networked system configuration that may be used in association with embodiments of the present invention. The representative system of FIG. 2 includes a computer device, illustrated as client 40, which is connected to one or more other computer devices (illustrated as clients 42) and one or more peripheral devices (illustrated as multifunctional peripheral (MFP) MFP 46) across network 38.

While FIG. 2 illustrates an embodiment that includes a client 40, two additional clients 42, MFP 46, and optionally a server 48, which may be a print server, connected to network 38, alternative embodiments include more or fewer clients, more than one peripheral device, no peripheral devices, no server 48, and/or more than one server 48 connected to network 38. Any of the computer systems illustrated in FIG. 2 may utilize and/or incorporate features discussed in any of the related applications such as base modules and peripheral modules as discussed in co-pending provisional application Ser. No. 61/407,904 (Attorney Docket Number: 11072.268) titled “MODULAR VIRTUALIZATION IN COMPUTER SYSTEMS” filed Oct. 28, 2010. Thus, any of the computer device 10, the client 40, the client 42, the server 48, etc. may include or consist of a base module and/or a peripheral module as disclosed in that application. Other embodiments of the present invention include local, networked, or peer-to-peer environments where one or more computer devices may be connected to one or more local or remote peripheral devices. Moreover, embodiments in accordance with the present invention also embrace a single electronic consumer device, wireless networked environments, and/or wide area networked environments, such as the Internet.

### Provision of Computing Resources Using Modular Device(s)

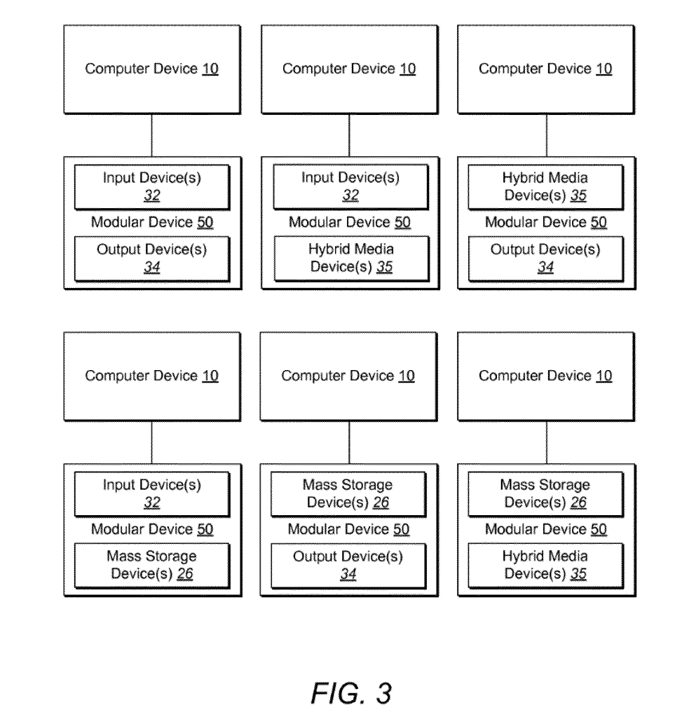

Certain embodiments of the invention permit the unification of multiple devices in a single modular device 50 as illustrated in FIG. 3. Modular devices 50 may include different devices and may be configured in a variety of ways, as is also illustrated in the depiction of FIG. 3. FIG. 3 depicts six different conceptual configurations of modular devices 50, each of which is further representative of potentially several different types of modular devices 50. Each modular device 50 may be selectively attached to the computer device 10 using any of a variety of communicative connections (e.g. wired connections such as USB, PCIe, IEEE 1394, eSATA, hybrid media bus, fiber optic, or any other standard or proprietary wired connection, wireless connections such as WiFi, WiMAX, infrared, other optical, or any other standard or proprietary wireless connection, and any other type of communicative connection now existing or later invented). The modular device 50 may be communicatively connected to the computer device 10 directly or through one or more additional communicative connections, such as through a network or modular computer system as discussed in some of the related applications.

Each modular device 50 includes one or more devices providing some functionality to the computer device. For example, as illustrated in the upper left depiction of FIG. 3, the modular device 50 may include one or a combination of one or more of the input devices 32 and one or more of the output devices 34. Alternatively, as illustrated in the upper central depiction of FIG. 3, the modular device 50 may include one or a combination of one or more of the input devices 32 and one or more of the hybrid media devices 35. Alternatively, as illustrated in the upper right depiction of FIG. 3, the modular device 50 may include one or a combination of one or more of the output devices 34 and one or more of the hybrid media devices 35. Alternatively, as illustrated in the lower left depiction of FIG. 3, the modular device 50 may include one or a combination of one or more of the input devices 32 and one or more of the mass storage devices 26. Alternatively, as illustrated in the lower central depiction of FIG. 3, the modular device 50 may include one or a combination of one or more of the output devices 34 and one or more of the mass storage devices 26. Alternatively, as illustrated in the lower right depiction of FIG. 3, the modular device 50 may include one or a combination of one or more of the mass storage devices 26 and one or more of the hybrid media devices 35. The specific modular devices 50 depicted and discussed with respect to FIG. 3 are intended to be illustrative only.

In at least some embodiments, the modular device 50 is “modular” in that it includes a single chassis or housing containing some, a majority, or all of the components making up the modular device. By communicatively connecting the modular device 50 to the computer device 10, resources of the modular device 50 are made available to the computer device 10. Because embodiments of the modular device 50 include or have the capability to include multiple devices, the resources of these multiple devices may be made available to the computer device 10 using a single communicative connection and using a single effective modular device.

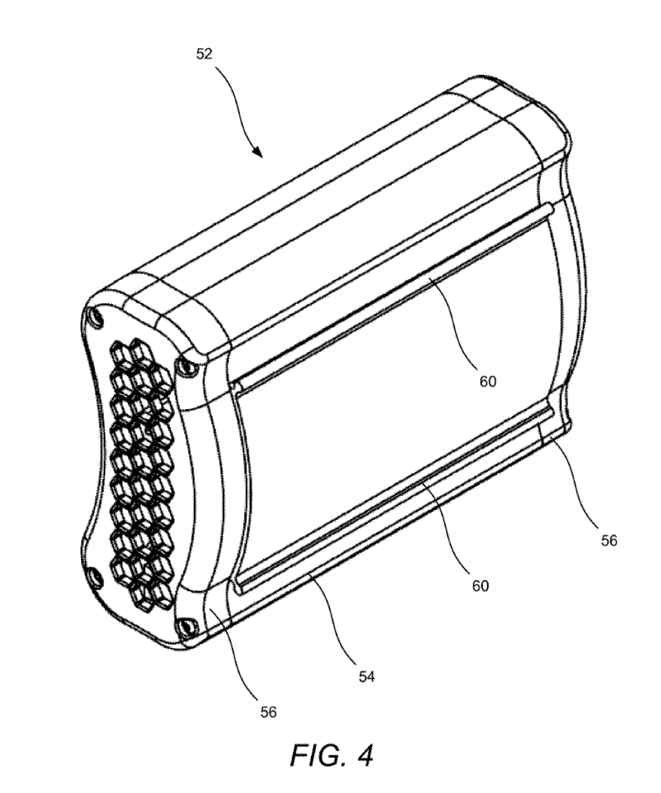

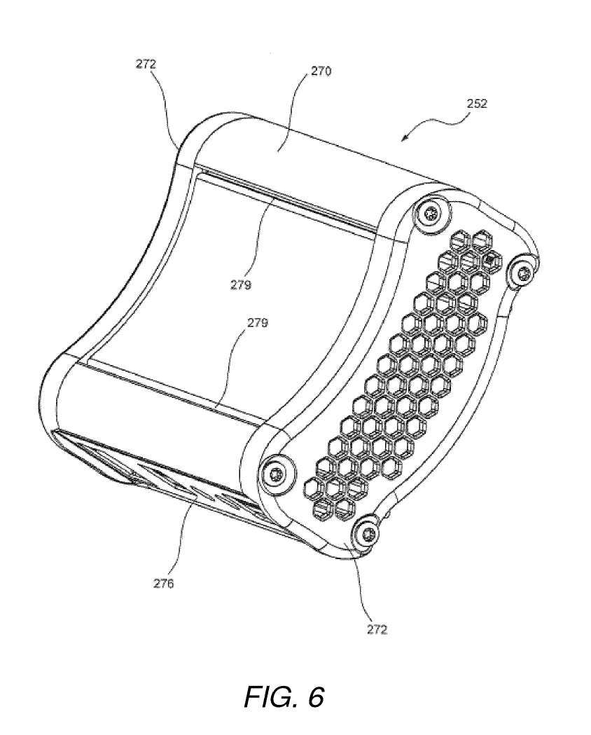

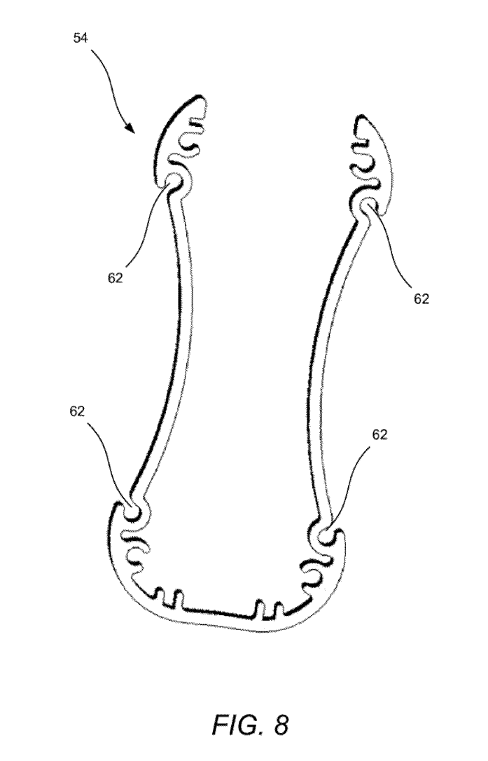

FIG. 4 shows a perspective view of one illustrative embodiment of a housing 52 that may be used for the modular device 50. As may be seen in this Figure, the housing 52 includes an outer structural shell 54 and two end caps 56. The structural shell 54 and end caps 56 serve to enclose and protect components of the modular device 50. The structural shell 54 may be made of a variety of materials, including plastics and metals, including aluminum and/or metal alloys, and may be formed in a way so as to provide structural functions as discussed in the related applications. Additionally, the structural shell 54 may be formed so as to mate with the structure of other modular devices 50 or other computer components as is illustrated in FIG. 8. Any ports provided to the modular device 50 may be provided at either end (e.g. by passing through one or more of the end caps 56) or along one of the edges of the modular device (e.g. by passing through an open end of the shell 54 or through an opening in a cover plate 58 closing an open end of the shell 54, as shown in FIG. 6.

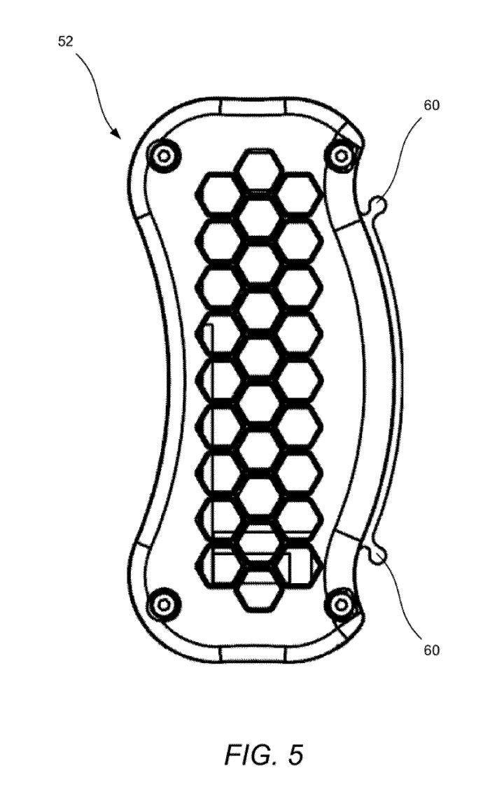

FIGS. 5 and 6 show end and perspective views of the housing 52, respectively. In these views and in the view of FIG. 4, some features of the structural shell 54 are visible that show one way in which mating with other devices may be accomplished. As may be seen in FIGS. 4 and 5, the structural shell 54 may be formed (e.g. extruded) to have a pair of mating protrusions 60 on one major side of the housing 52. As may be seen in FIG. 6, the opposite major side of the structural shell 54 in this embodiment is formed to have a corresponding pair of mating channels 62 that can accept the mating protrusions 60. As may also be seen in FIGS. 4 through 6, the end caps 56 do not include either the mating protrusions 60 or the corresponding mating channels 62. The other device includes corresponding mating channels 62 or mating protrusions 60 on at least one of its sides (but again, not on its corresponding end caps), as illustrated in FIG. 8.

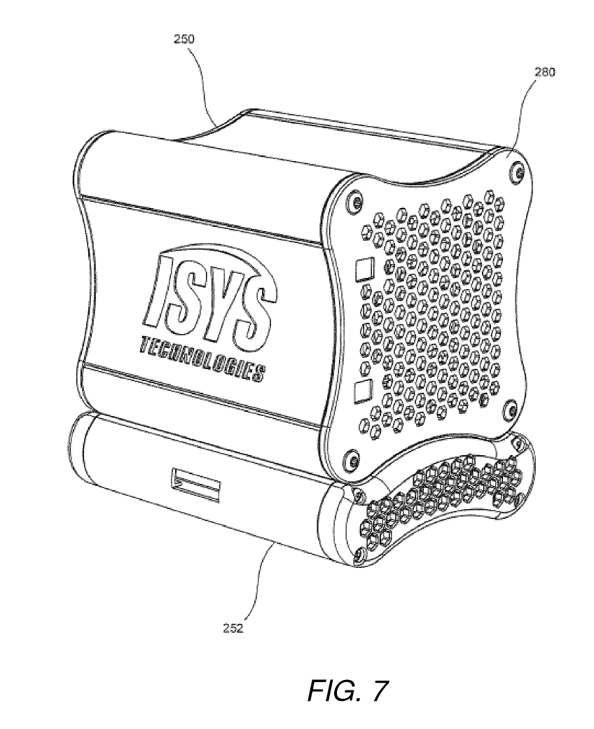

To structurally attach the modular device 50 to some other device, such as computer device 10 in the manner shown in FIG. 7, an end cap 64 of the computer device 10 is removed (tamper-resistant fasteners may be used to deter theft or vandalism), and the mating protrusions 60 of the modular device 50 are slidingly engaged with the corresponding mating channels 62 of the computer device 10. The modular device 10 slides until it is fully mated with the computer device 10. The end cap 64 of the computer device 10 is reattached to the computer device 10 and thereby locks the modular device 50 to the computer device 10. Additional modular devices 50 or other components may be attached to the system using the mating channels 62 of either the modular device 50 or of other sides of the computer device 10 as desired, with the corresponding end cap (56 or 80) being removed to facilitate such attachment.

The illustrated embodiments shown in FIGS. 4-7 are merely illustrative of ways that embodiments may be constructed to permit structural connections between modules and with other devices. Thus, for example, while the illustrated housing 52 has mating protrusions 60 on one major side and mating channels 62 on another major side, another embodiment may have mating channels 62 on both major sides, as illustrated in the end view depiction of an alternate outer structural shell 54 shown in FIG. 8.

The structural shell 54 of the may be load bearing as disclosed in one or more of the related applications. The modular device 50 may therefore be used as a mount from which to hang a monitor or other device, may be embedded or mounted in a wall, may be a part of a frame, and may perform any of the structural functions disclosed in the related applications. For example, a plate may be mounted to a wall and another plate may be mounted to a monitor, and the two plates may be connected together through the structural features of the modular device.

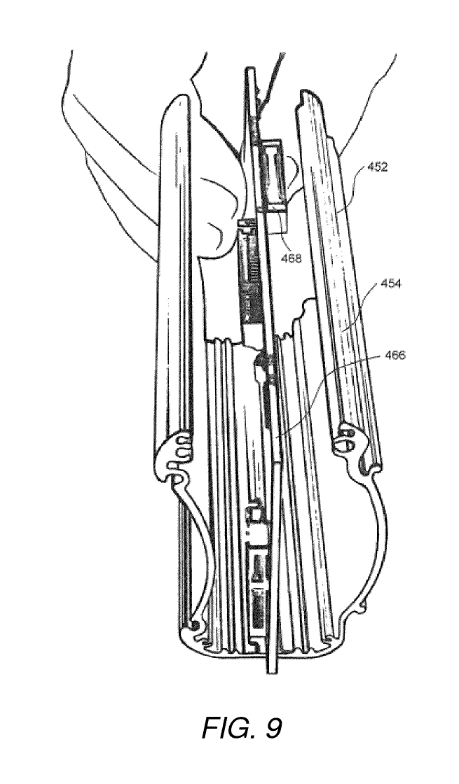

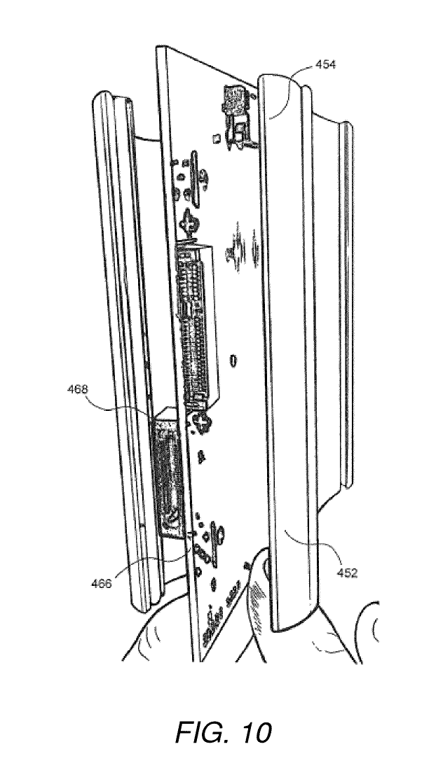

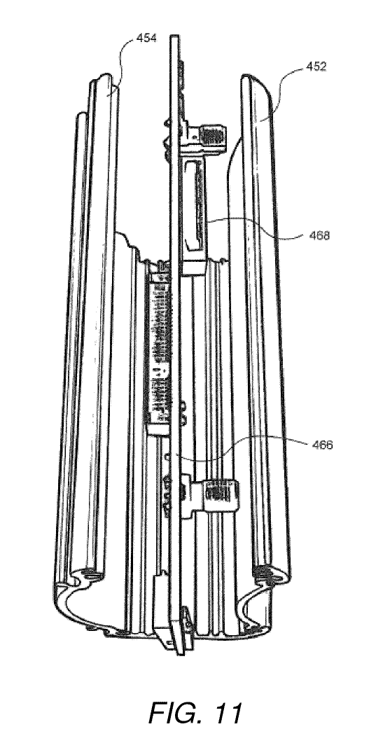

To allow the housing 52 to contain multiple devices as illustrated in FIG. 3, embodiments of the invention utilize a bilateral printed circuit board (PCB 66) that can be mounted within the housing 52 as illustrated in FIGS. 9 through 11. The PCB 66 may be mounted in a channel (not shown) or other mounting structure provided in the interior of the shell 54 so as to be more-or-less centrally mounted within the housing 52. The PCB 66 provides both structural support for mounting any components or devices thereon and communicative coupling between any components or devices mounted thereon and to one or more ports 68 or other communicative devices providing communication between the components or devices and any computer device communicatively connected to the modular device 50.

In at least some embodiments of the present invention, the PCB is part of a board system that includes a plurality of printed circuit boards. In one embodiment, the board system includes a plurality of interconnected printed circuit boards wherein at least one of the boards is connected transverse to another one of the boards. In another embodiment, the board system includes a plurality of interconnected printed circuit boards wherein at least one of the boards is connected in a parallel manner to another one of the boards. In at least some embodiments, the board configuration is a tri-board configuration. In a further embodiment, the tri-board configuration includes two parallel boards interconnected by a third board that is transverse to the two parallel boards. In another embodiment, a first board has a second board connected transversely on once side of the first board and a third board connected to the first board so as to be parallel to the first board. Those of skill in the art will appreciate that embodiments of the present invention one or more boards in a board system, having any of a variety of configurations.

The centralized mounting of the PCB 66 permits mounting of components and/or devices on both sides of the PCB 66 in a novel fashion. This mounting facilitates compact modular devices 50 providing functionality not available in current devices. For example, in a modular device 50 providing primarily storage functionality, mass storage devices 26 may be mounted on both sides of the PCB 66, thus providing for two mass storage devices 26 within the same housing using a single PCB 66 in a compact amount of space. Meanwhile, if the storage capabilities of multiple mass storage devices 26 are not needed, the same PCB 66 may be used in conjunction with a single mass storage device 26.

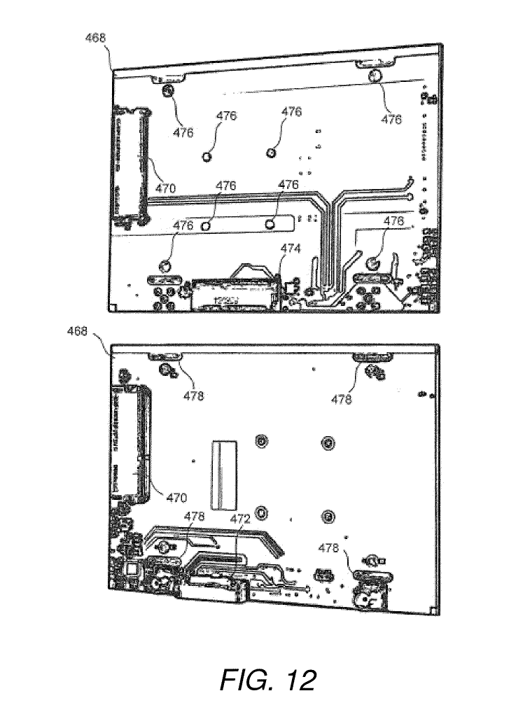

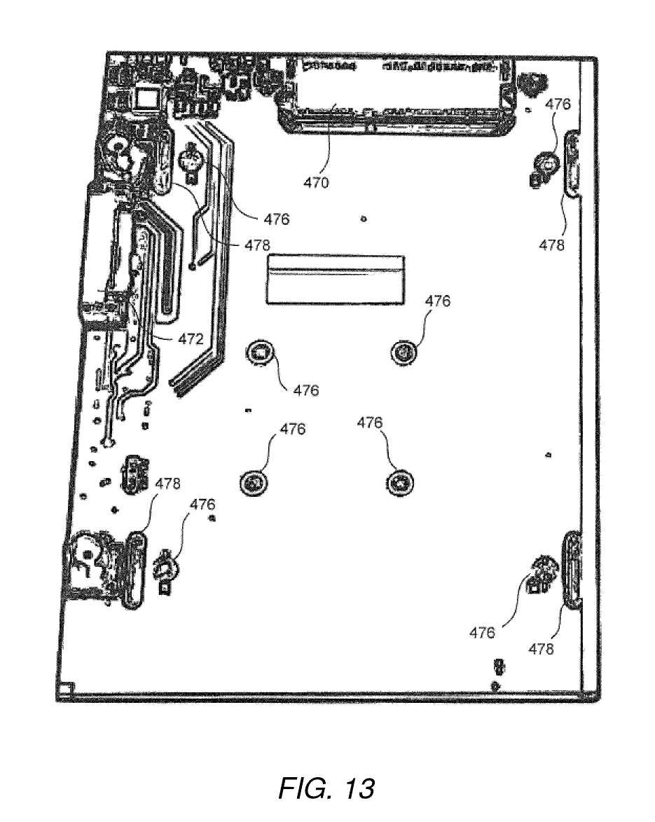

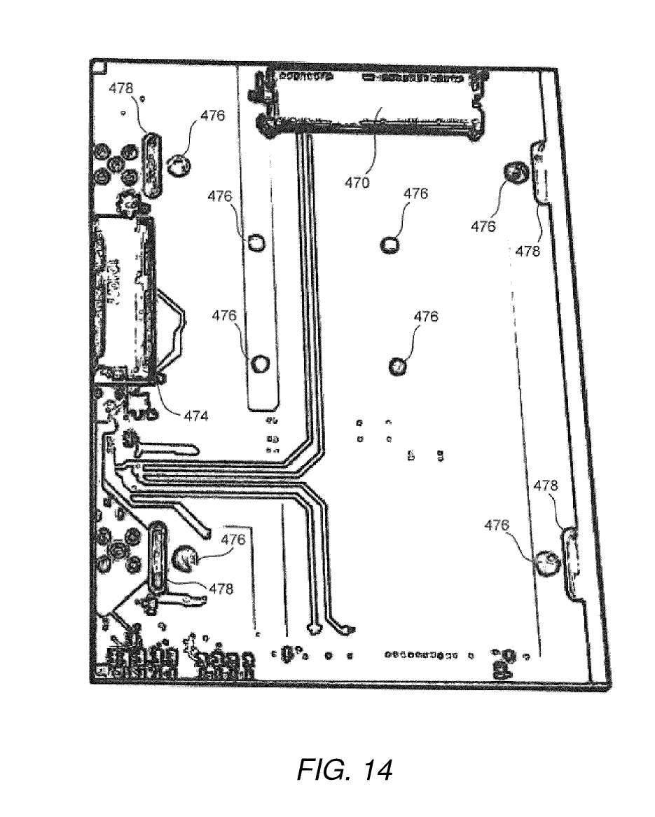

One manner in which this may be achieved may be appreciated by reference to FIGS. 12 through 14, which provide depictions of an exemplary embodiment of the PCB 66. FIG. 12 shows a side-by-side comparison of front and back views of the PCB 66, while FIG. 13 shows a larger view of just the front side and FIG. 14 show a larger view of just the back side of the PCB 66. As may be seen in these Figures, a connector 70 for connecting a mass storage device (such as a hard drive, solid-state drive, hybrid drive, and the like) is provided on each of the front and back sides of the PCB 66. In the illustrated embodiment, the connectors 70 are disposed to be on opposite longitudinal ends of the PCB 66 as well as on opposite faces of the PCB 66, but in other embodiments, the connectors 70 may be disposed on a single longitudinal end.

One face of the PCB 66 also includes a port connector 72 that provides the port 68 discussed previously. It should be noted that the illustrated port 68 and/or port connector 72 is merely intended to be illustrative: multiple ports 68 and/or port connectors 72 may be provided, these port(s) 68 and/or port connector(s) 72 may be provided at other locations and/or sides of the PCB 66, and any desirable type of port 68 and/or port connector 72 may be provided, or no port 68 or port connector 72 may be provided when some other communicative mechanism is to be used.

The other face of the PCB 66 in the illustrated embodiment is provided with an additional device connector 74 that may be similar or different from the connectors 72. For example, the device connector 74 may be of a type optimized for connection of devices other than mass storage devices. As with the port connector(s) 72, the type, location, and number of the device connectors) 74 illustrated in FIGS. 12-14 is merely illustrative, and varying types and numbers of device connectors 74 may be provided, including embodiments with no device connectors 74.

To facilitate mounting of one or more devices to the PCB 66, the PCB 66 of the illustrated embodiment is provided with several features. The first feature is a plurality of direct mounting holes 76 passing through the PCB 66. The number and placement of the direct mounting holes 76 illustrated in FIG. 12 is merely illustrative, and may be varied according to the specific needs of each embodiment. In certain embodiments, no direct mounting holes 76 are provided, and in other embodiments, any number of direct mounting hole(s) 76 greater than zero may be present.

The direct mounting holes 76 may be used to mount a component or device directly to the PCB 66. For example, in the illustrated example, the more-centrally located direct mounting holes 76 may be used to mount a smaller component to one side of the PCB 66 by way of inserting fasteners such as threaded fasteners through the direct mounting holes 76 into corresponding threaded holes on the smaller component. The more-exterior direct mounting holes 76 may be used to mount a larger component to the other side of the PCB 66 by way of inserting fasteners through the direct mounting holes 76 in the opposite direction into corresponding threaded holes on the larger component. As long as any potential short-circuit issues that could be potentially caused by contact of one of the mounted components to the fasteners are avoided (such as by spacers, insulation, etc., the direct mounting holes 76 may be used to directly attach two components or devices in this fashion on opposite sides or faces of the PCB 66.

Of course, it will be realized that where only a single component or device is needed, only one set of the direct mounting holes 76 would be used and a component or device would only be located on a single side of the PCB 66. The other side of the PCB 66 would remain available for mounting of another device at a later time. Depending on the type of device(s) or component(s) and its/their communicative and/or power connection(s) to the PCB 66, the mounting procedure may entail first inserting the device/component into the applicable connector(s) (e.g. connector 70) and then securing the device/component to the PCB 66, or it may entail separately making a communicative/power connection between the device/component and the applicable connector(s) either before or after mounting the device/component to the PCB 66.

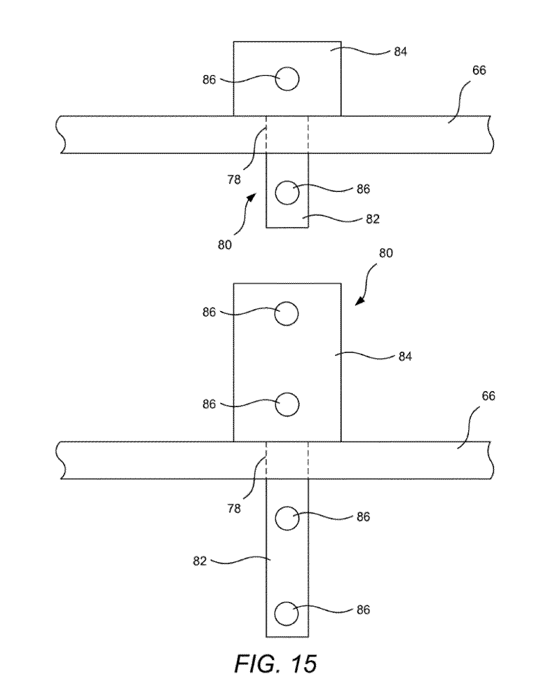

While the direct mounting holes 76 may permit mounting of a wide variety of devices to the PCB 66 and may even permit mounting of devices on both sides or faces of the PCB as discussed above, it is anticipated that it may not be possible to use the direct mounting holes 76 to mount devices on both sides of the PCB 66 in all circumstances. For example, the first-mounted component or device may obscure one or more needed direct mounting holes 76, thereby preventing mounting of the second component or device. Therefore, embodiments of the invention utilize an indirect mounting slot 78 as shown in FIGS. 12-14. The mounting slot 78 is adapted to receive a T-shaped connector 80 as shown in FIG. 15. The T-shaped connector 80 is a flat element having a narrow end 82 adapted to be inserted into and received by the indirect mounting slot 78 and a wide end 84 that is wider than the indirect mounting slot 78. Thus, the narrow end 82 of the T-shaped connector can be inserted into the indirect mounting slot 78 until the wide end 84 contacts the PCB 66, stopping further entry of the T-shaped connector. In at least some embodiments, the T-shaped connector may be soldered into place after insertion into the indirect mounting slot 78.

Both the narrow end 82 and the wide end 84 have at least one connector mounting hole 86 therein. As illustrated in FIG. 15, different embodiments of the T-shaped connector may be provided with more or fewer connector mounting holes 86 placed to be on each side of the PCB 66. Of course, it will be appreciated that while the lower version of the T-shaped connector 80 shown in FIG. 15 may permit the mounting of additional component(s) or device(s) on each side of the PCB 66, it will require a housing 52 of greater internal volume than the upper version of the T-shaped connector 80 shown in FIG. 15. The connector mounting holes 86 accept fasteners such as threaded fasteners therethrough and into one or more components to be mounted on the PCB 66 indirectly by way of the T-shaped connector 80. While two embodiments of the T-shaped connector 80 are shown in FIG. 15, other embodiments may have more connector mounting holes 86 than the number shown, and still other embodiments may have differing numbers of connector mounting holes 86 on the narrow end 82 compared with the wide end 84.

In certain embodiments, the T-shaped connectors 80 may be used in conjunction with the direct mounting holes 76 to mount multiple devices/components to opposite sides of the PCB 66, or may be used independently from the direct mounting holes 76 (if even present) to mount multiple devices/components to opposite sides of the PCB 66. If the direct mounting holes 76 are used, the first component is mounted to the PCB 66 using the direct mounting holes 76 first. Afterward, the T-shaped connectors 80 are used to mount a second device on an opposite side of the PCB 66. If the T-shaped connectors 80 allow mounting of additional device(s)/component(s), it or they may be mounted in like fashion.

Many hard drives, for example, have threaded receptacles in both the bottom and sides of the hard drives. The bottom threaded receptacles may be used in conjunction with at least some of the direct mounting holes 76, and the side threaded receptacles may be used in conjunction with at least some of the T-shaped connectors 80. Of course, placement of the direct mounting holes 76 and the indirect mounting slots 78 may be chosen to facilitate mounting in the described fashions. As will be appreciated, the size of the modular device 50, the PCB 66, and the placement of the various holes and connectors may be varied as desired and selected in accordance with the anticipated devices/components to be used in the modular device 50.

Embodiments of the invention may be used in a wide variety of fashions to provide advantages not currently available in the art. The additional three-dimensional connection arrangements provided by embodiments of the invention reduce the volume needed for equipment while still permitting adequate air flow and cooling capability. Additionally, such arrangements permit the connection of multiple devices of varying types within a single component as discussed above with respect to FIG. 3.

As another example, a modular device 50 may be configured as a storage device. While the modular device 50 may function essentially as a standard enclosure for a single mass storage device, the modular device 50 may also provide, in a single package, storage options not currently available. For example, if the modular device 50 is configured to contain up to two mass storage devices, a first mass storage device may be chosen according to first desirable performance or other characteristics, while the second mass storage device may be chosen according to second desirable performance or other characteristics. As one specific example, some users may desire the high performance characteristics of solid-state drives for storing operating systems (OSs) and application programs, while desiring the inexpensive large storage capability of spinning magnetic drives for storing all other data. Other users may desire only maximum capacity, while still other users may desire only maximum performance.

Embodiments of the invention cater to these specific desires in a flexible fashion. The modular device is simply provided with two drives: a solid state drive of appropriate capacity for the OS and application programs, and a spinning magnetic drive of appropriate size for the other data. Of course, different users may need different sizes of the two drives and may customizably select their drive capacities differently accordingly. Additional benefits are available as well: where existing hybrid drives usually have limited solid state capacity and can never have that capacity changed, any size of solid state drive may be initially chosen for the modular device 50, and can easily be swapped out at a later point in time for a drive of a different size without requiring replacement of the entire modular device 50. Similarly, if a user later needs additional capacity of the spinning magnetic drive or later desires the higher performance of a solid state drive, a similar change is made.

Another example may be realized by the combination of differing types of devices or components within the modular device 50. For example, an embodiment may be provided that provides features associated with digital video recording (DVR) technology. Thus, one of the devices or components within the modular device 50 may be a mass storage device, and another device or component may be a video capture component. In such an embodiment, a port may be provided to receive video signals (e.g. from an antenna or from a cable device), or an internal or external antenna may be attached to the modular device 50.

As another example, a wireless card or device could be mounted on one side of the PCB 66, and could allow the modular device 50 to communicate wirelessly with one or more remote devices. Some embodiments may be provided with a graphics card or device mounted on one side of the PCB 66 for outputting video signals. Indeed, any device that could be plugged into any port or connector provided on the PCB 66 (e.g. mini PCI, mini PCIe, etc.). Supporting mechanical and electronic devices can be connected to the modular device 50 as desired to provide additional features and functionality.

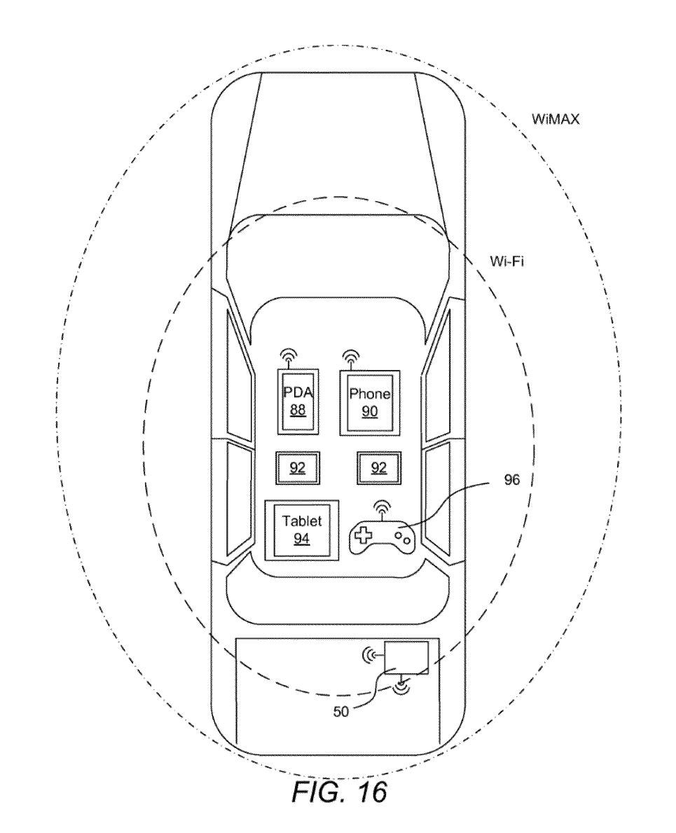

As another example, a modular device 50 could be provided with a mass storage device and a dual-band wireless device on opposite sides of the PCB 66. The dual-band wireless device may provide local WiFi connections to other devices in proximity of the modular device 50 (e.g. PDA 88, phone 90, display 92, tablet computer 94 (or any other computing device), and controller 96) while simultaneously providing longer-range WiMAX connections to permit accessing of external content, as illustrated in FIG. 16. Meanwhile, the mass storage device could provide storage and applications, including to external modules relying on the modular device 50 for providing computing capabilities.

### Modular Packaging

As provided above, embodiments of the present invention relate to dynamically modular packaging. More particularly, embodiments of the present invention relate to systems and methods for providing modular packaging, including modular packaging of computer systems, devices, and/or components.

In at least some embodiments, the modular packaging includes a base that is configured to receive any of a number of tops or lids, wherein the particular top or lid used in association with the base is determined based upon the size of the volume needed within the overall packaging to contain, support and/or protect the contents inside the packaging. In at least some embodiments, the base includes a bottom portion and a top portion. The combination of the top and bottom base portions forms a cavity for inclusion, for example, of components, connectors, cables, manuals, materials, and other items that are able to be packaged along with the computer device or other item that is being provided within the modular packaging. The top portion of the base provides a mounting platform with a connector system to selectively mount the computer device or other item being packaged. The lid or top is configured to cover the computer device or item to be packaged and mate with the base to form an enclosure. In some embodiments, an outer skin or covering is provided over the top and base combination.

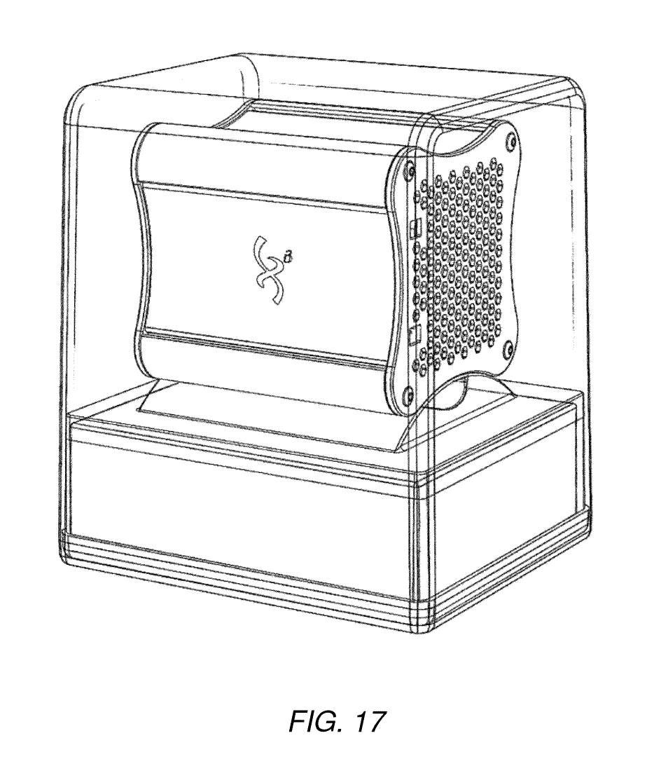

With reference now to FIGS. 17-23, various views of modular packaging are shown in accordance with a representative embodiment of the present invention. In FIG. 17, a computer device is shown in association with modular packaging. The modular packaging includes a base that is configured to couple with, receive, or otherwise mate with a top or lid. The size of the top or lid is determined based on the size of volume needed within the packaging, however the base is a universal base configured to receive any of a number of different tops or lids. The base includes a top portion coupled to a bottom portion, thereby defining an inside cavity for cords, materials, manuals, or other items associated with the device or product being packaged.

In at least some embodiments of the present invention the packaging comprises a polymer material. In a further embodiment, the polymer material is transparent in at least some areas to allow a user to see the product or device being packaged and/or to be able to allow marketing material to be seen through the packaging. In some embodiments, that packaging material is laser etched, obscured, and/or printed on. In some embodiments, at least part of the packaging is opaque. In some of the embodiments, other non-polymer materials are used, including metals, metal alloys, wood, etc.

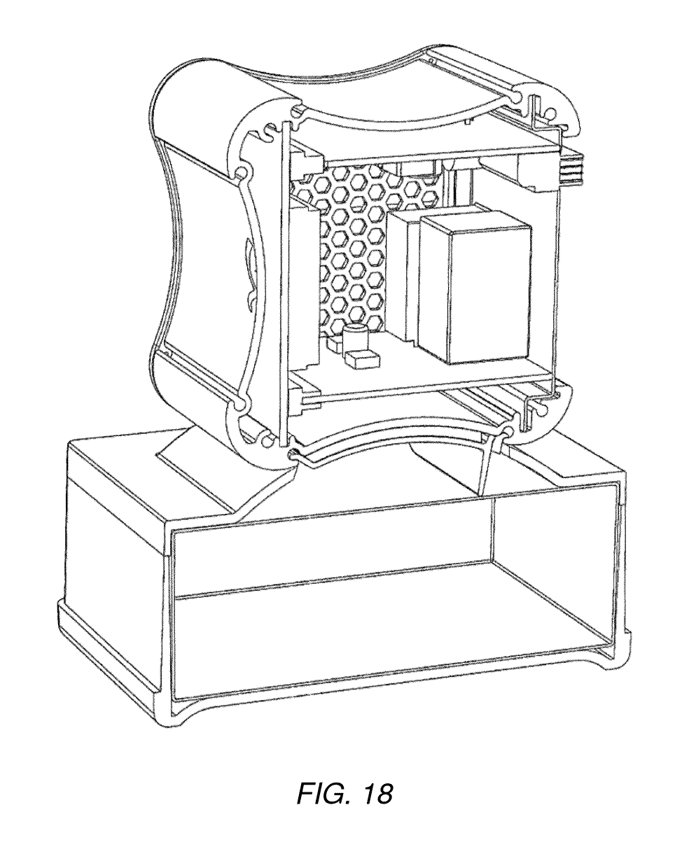

With reference to FIG. 18, a cross-sectional view of the embodiment of FIG. 17 is shown. In FIG. 18, the top or lid has been removed. The computer device is mounted onto the base. In the illustrated embodiment, the mounting utilizes mating protrusions of the packaging material that are configured to mate with mating channels of the computer device chassis. The computer device is mounted onto the top of the base through use of a connector system that includes one or more mating protrusions. As illustrated in FIG. 18, the combination of the top portion and the bottom portion of the base form a storage cavity.

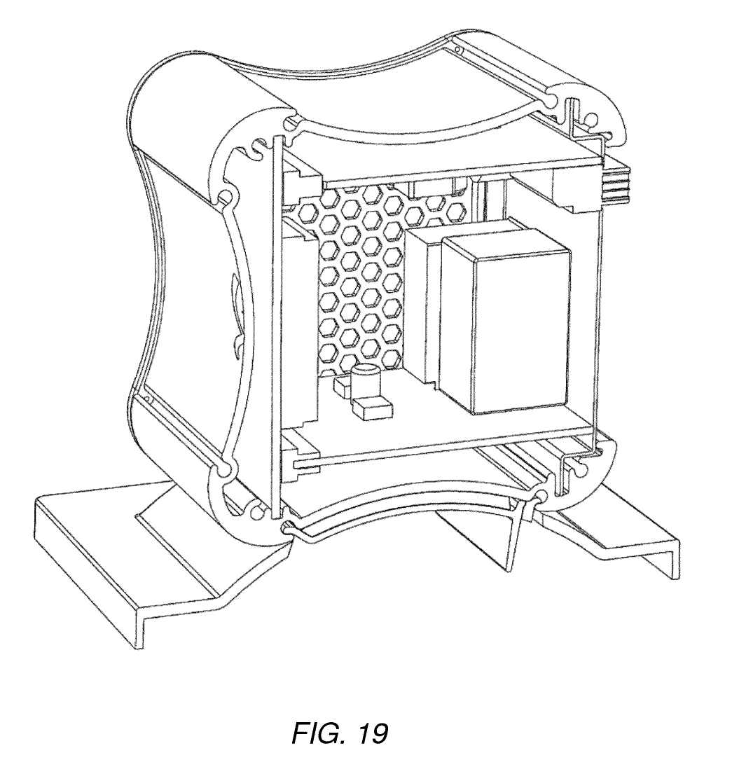

FIG. 19 illustrates the mounting of the computer device to the top portion of the base. In FIG. 19, the bottom portion of the base is removed. The mounting platform with a connector system having one or more mating protrusions is shown. In the illustrated embodiment, the mating protrusions are received by the mating channels of the computer device chassis. In some embodiments, the protrusions are able to be inserted directly into the mating channels. In other embodiments, one or more of the end caps of the computer device are removed to allow the protrusions to slide into the mating channels of the computer device chassis.

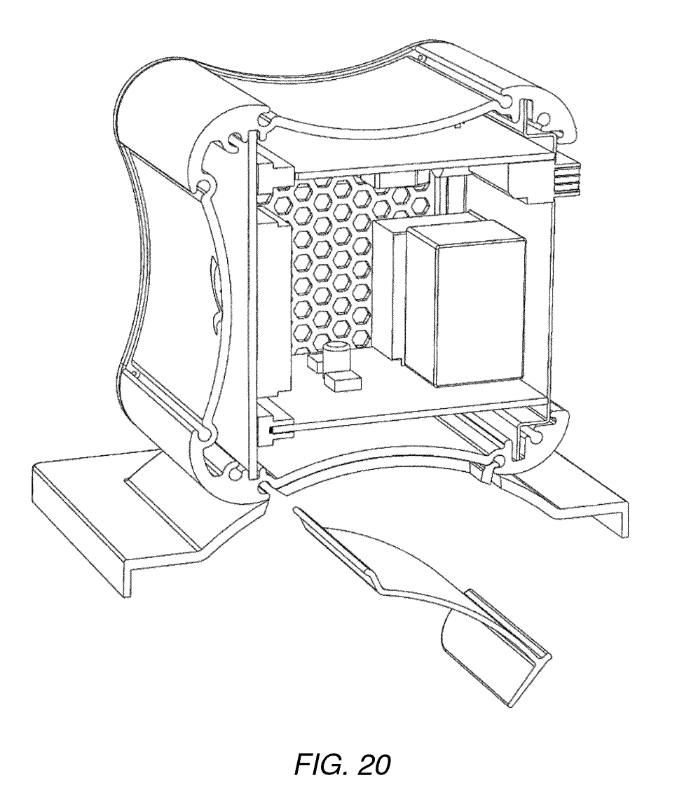

FIG. 20 illustrates the removal of a locking device of the connector system. The locking device includes a plurality of mating protrusions that are selectively inserted or removed from the mating channels to selectively couple or decouple the computer device from the mounting platform or top portion of the base. In the illustrated embodiment, the top portion of the base includes a plurality of slots to allow the mating protrusions of the locking device to extend through the slots and selectively couple or otherwise be inserted into the mating channels of the computer device.

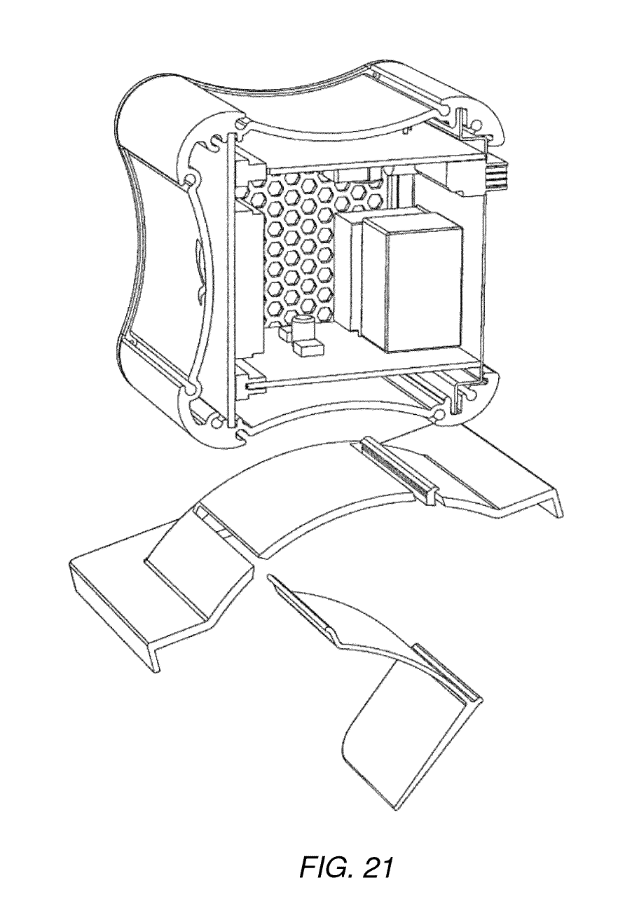

FIG. 21 illustrates an exploded view of the embodiment of FIG. 20, with the locking device separated from the top portion of the base and from the computer device. FIG. 21 further illustrates the plurality of slots formed in the top portion of the base. In some embodiments, as illustrated in FIG. 21, a protrusion is located on the top portion of the base for insertion into one of the mating channels of the computer device.

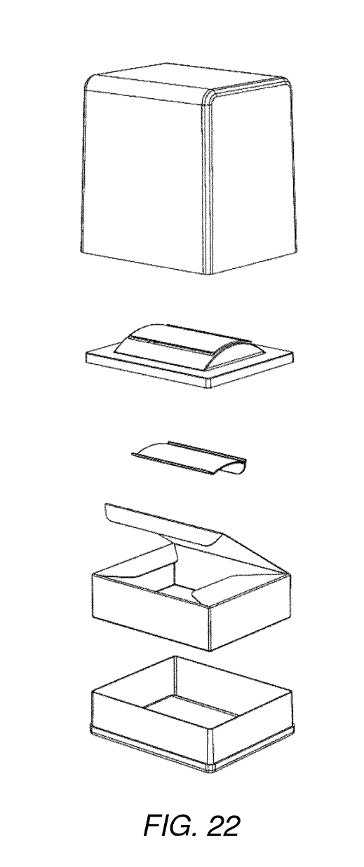

FIG. 22 illustrates an exploded view of the various components of the packaging, namely (from top to bottom) a top or lid, a top portion of the base, a locking device, an insert that can be selectively housed within the inside cavity formed by the combination of the top and bottom portions of the base, and a bottom portion of the base.

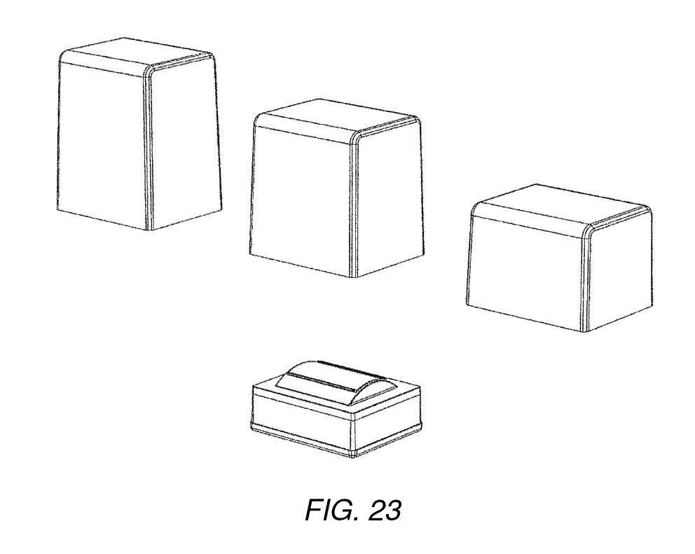

FIG. 23 illustrates that in association with at least some embodiments of the present invention, a standard base is used that can selectively receive any of a plurality of tops or lids depending on the amount of volume needed within the modular packaging to house the particular item or device being packaged.

In some embodiments, a bottom portion of the base is provided that has shorter or longer side walls to allow for a smaller or larger volume of the inside cavity of the base.

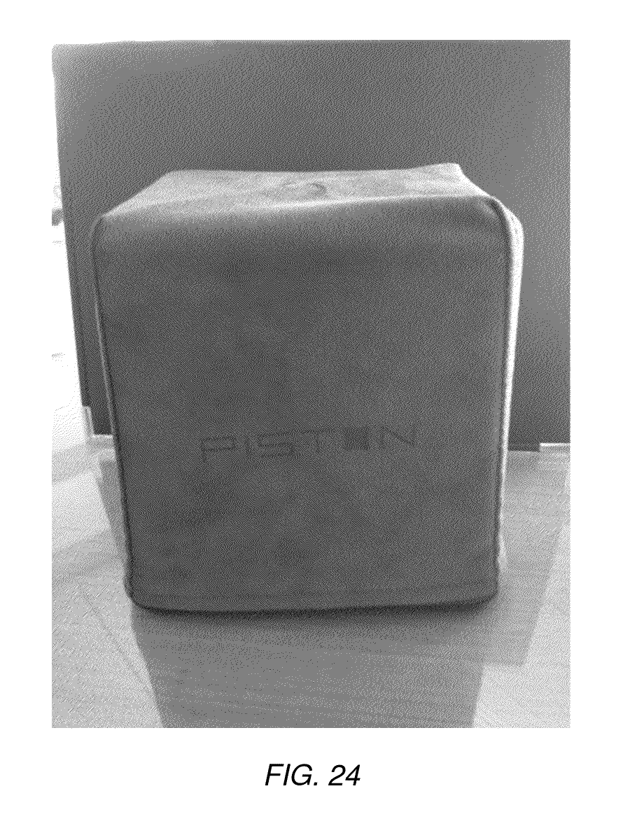

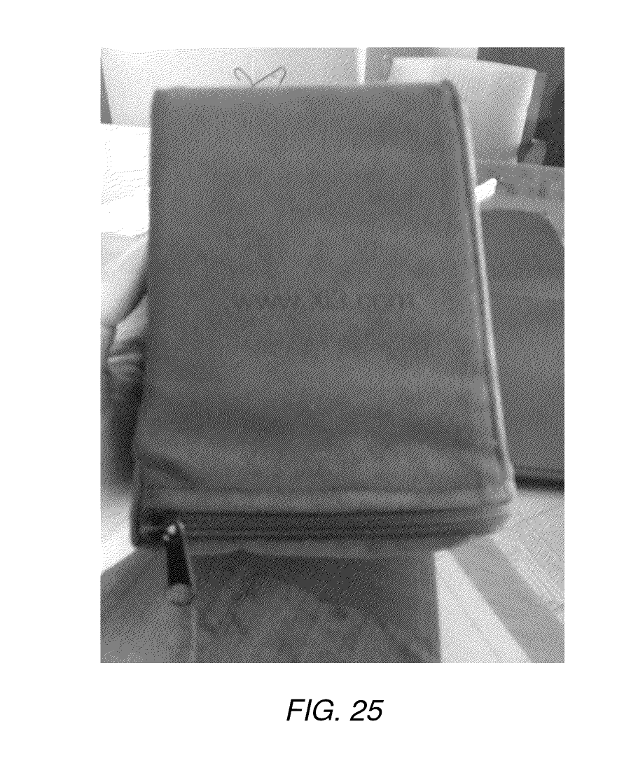

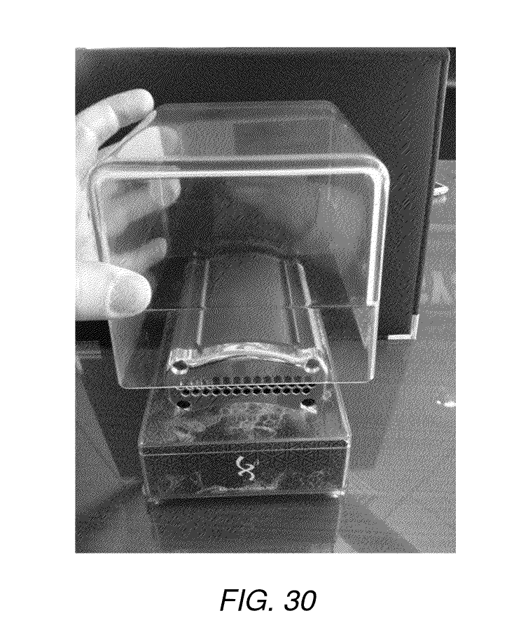

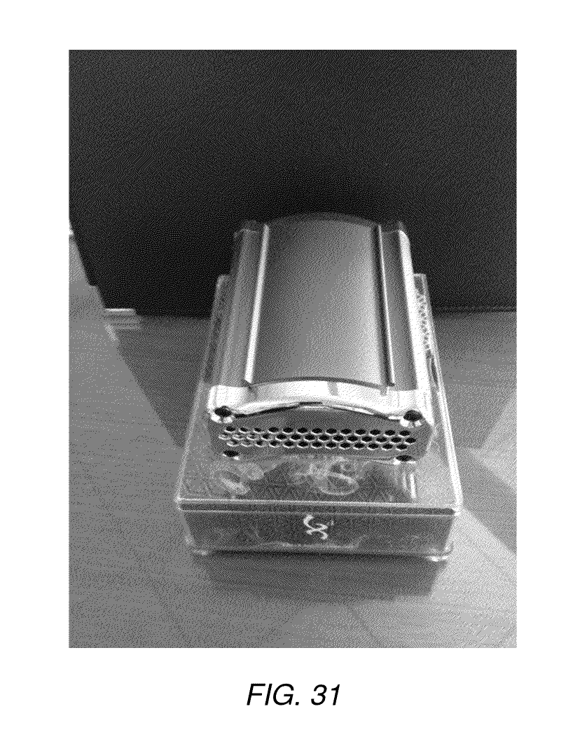

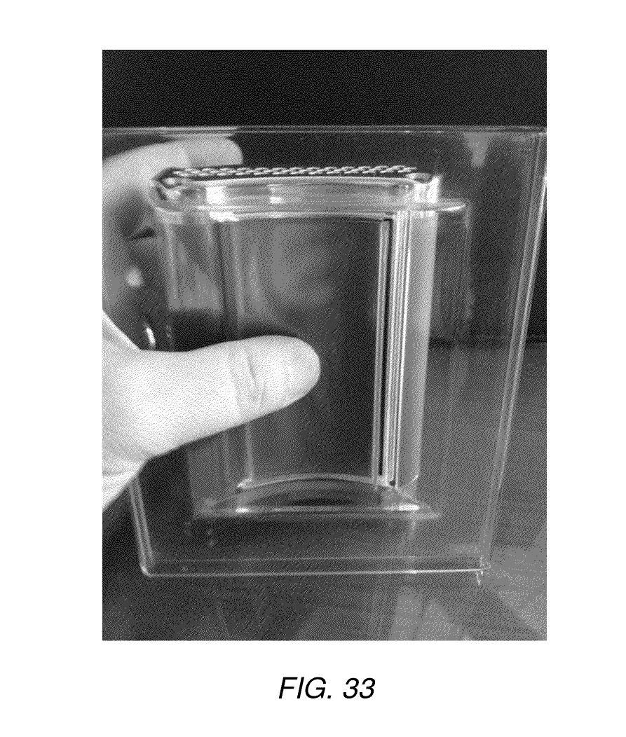

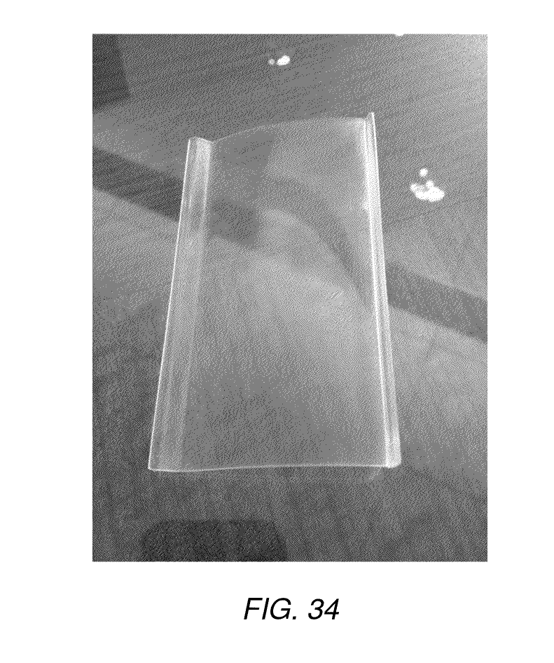

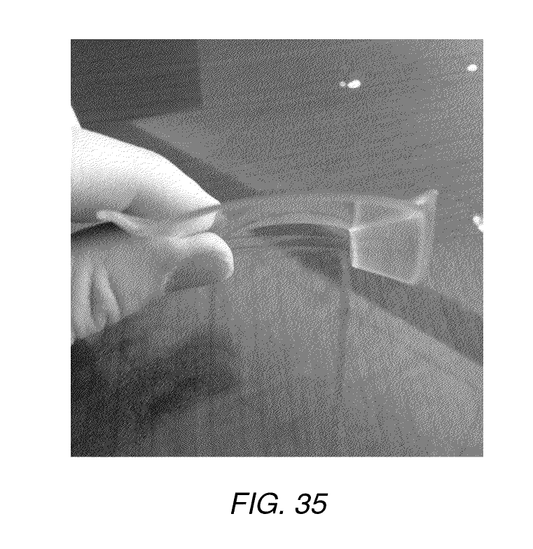

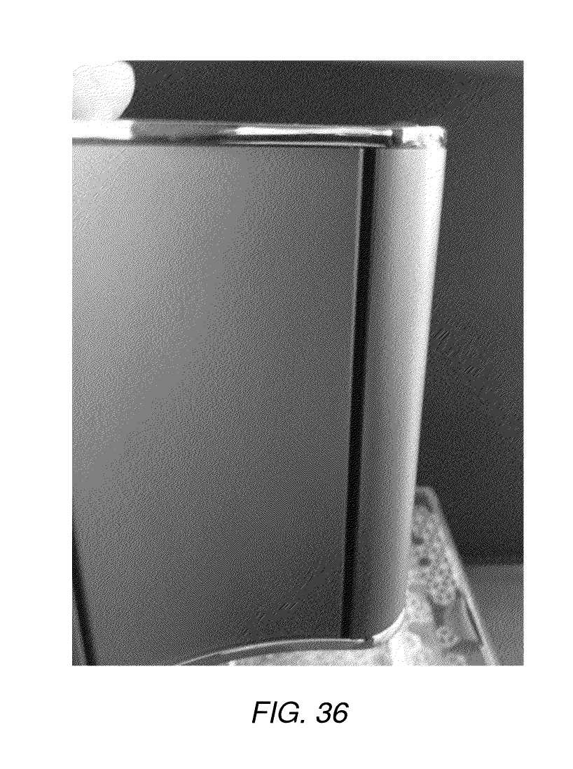

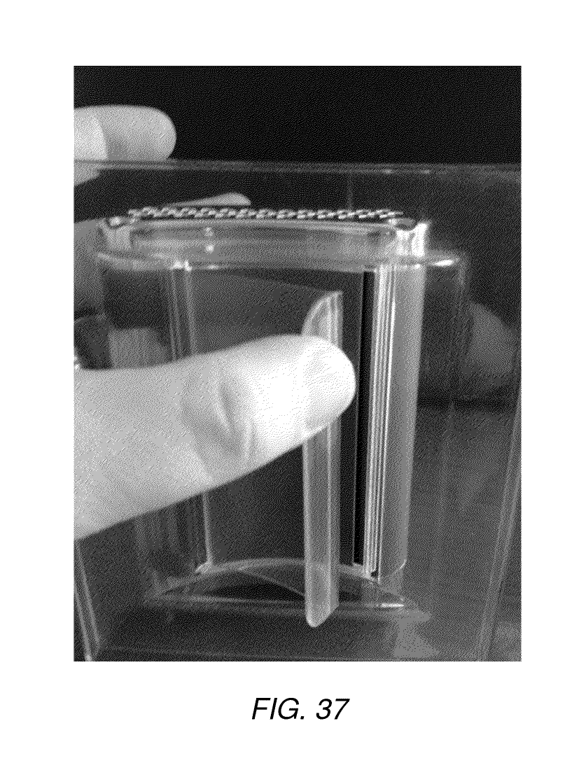

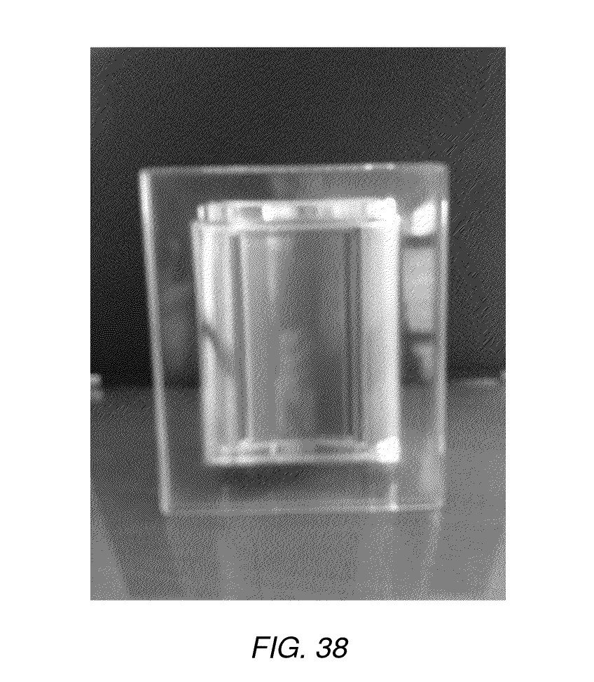

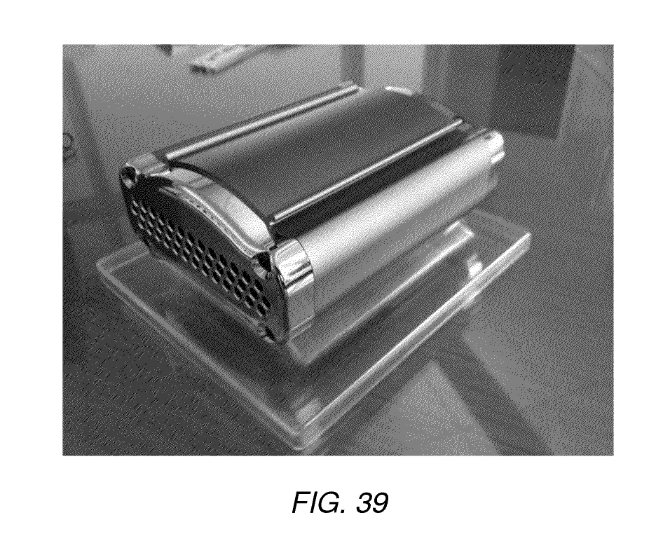

FIGS. 24-43 show various views of modular packaging in accordance with another representative embodiment of the present invention. In FIG. 24, a skin or covering is shown that is selectively provided over the top and base combination of the modular packaging. In the illustrated embodiment of FIGS. 24-25, the skin or covering comprises a fabric material and includes a zipper. Those of skill in the art will appreciate that the skin or covering can comprise a variety of materials, including leather, paper, polymer, or another material. Further the skin or covering can include a variety of fastening devices, including a zipper, snaps, an adhesive, a weld, a loop and fastener system, or another fastening device.

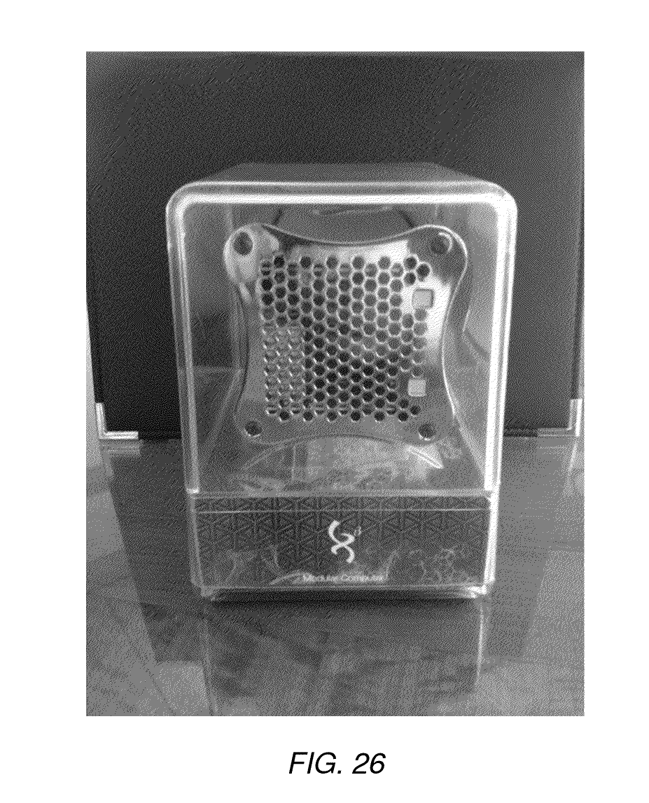

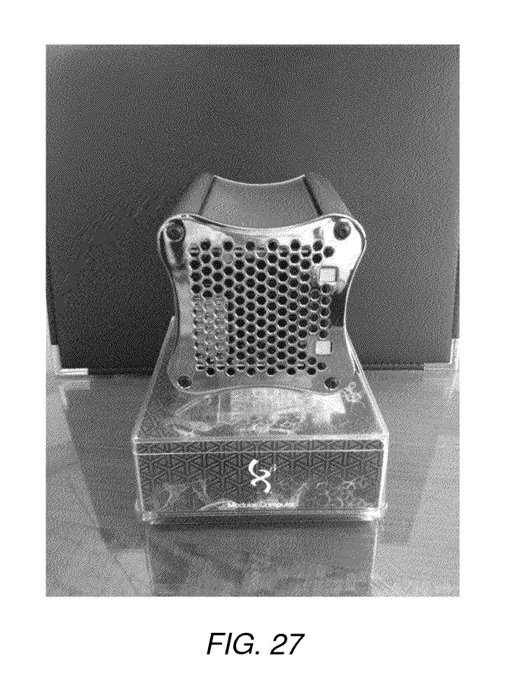

FIGS. 26-27 illustrates an embodiment of the modular packaging used to contain a computer device, wherein FIG. 26 includes the top or lid of the modular packaging and FIG. 27 has the top or lid removed.

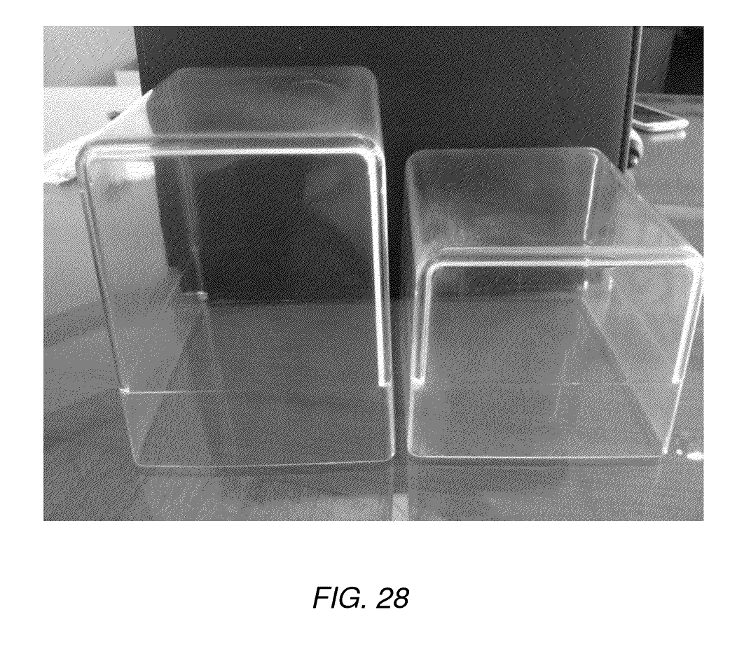

FIG. 28 illustrates a plurality of tops or lids that can be used in association with a base to selectively provide a needed volume within the modular packaging.

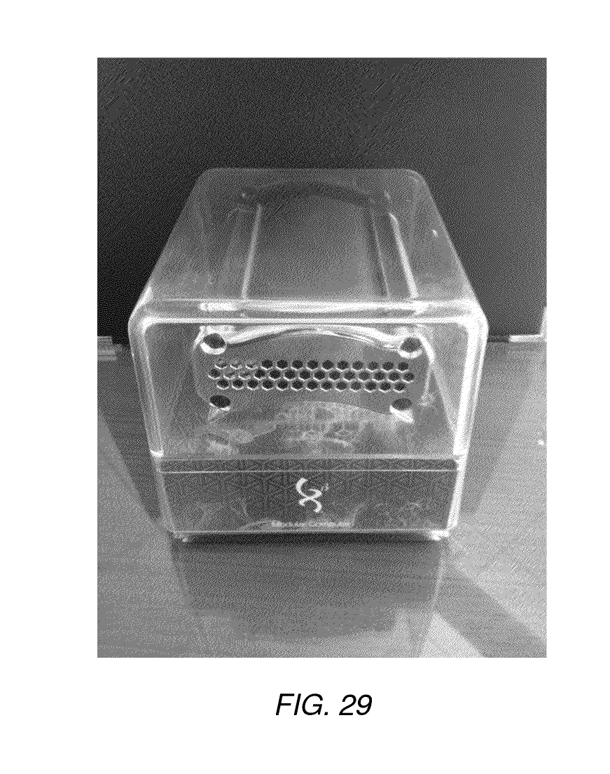

FIGS. 29-31 illustrate use of a smaller top or lid as compared to FIGS. 26-27, but with the same base as in FIGS. 26-27. This allows for a smaller volume within the modular packaging.

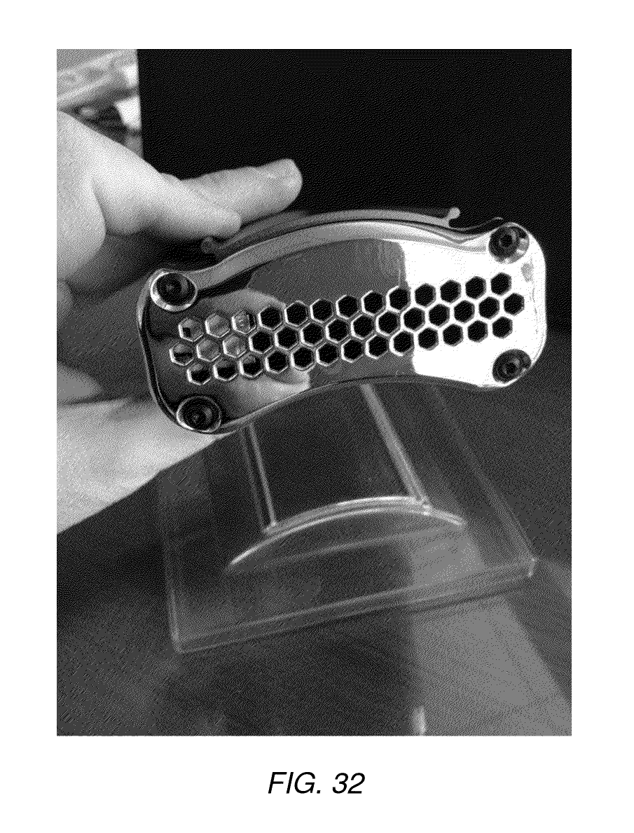

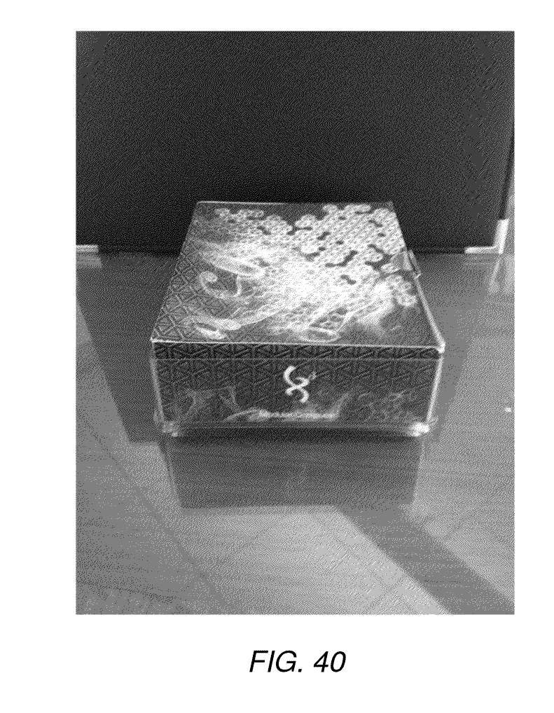

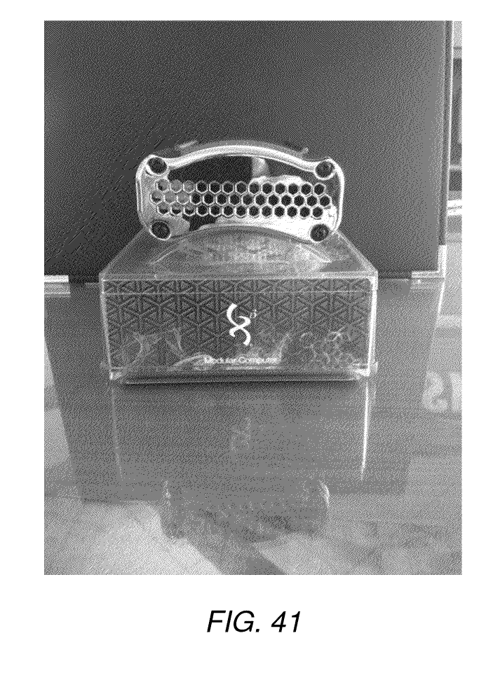

FIGS. 32-39 illustrate utilization of mating protrusions and corresponding mating channels to selectively couple or decouple a computer device or other product from the top portion of the base. FIG. 40 illustrates the bottom portion of the base. FIG. 41 illustrates the bottom portion of the base coupled to the top portion of the base.

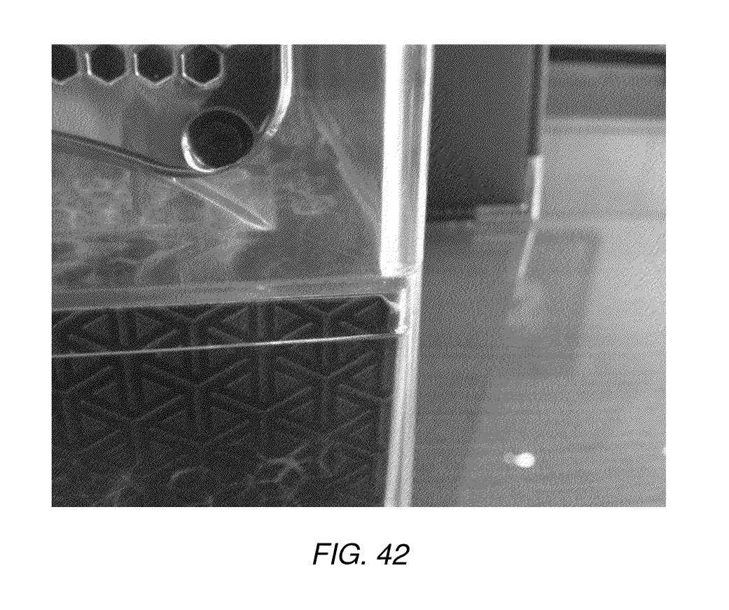

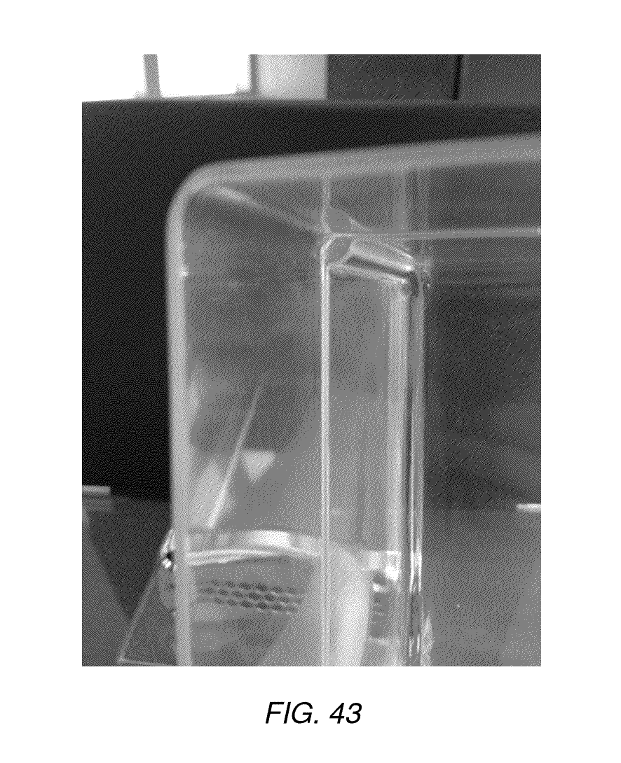

In FIG. 42, the top or lid is coupled with the base. In some embodiments, as show in FIG. 43, a surface is provided in the top or lid to connect with, rest upon, or otherwise couple with the top portion of the base. In some embodiments, the coupling of the top or lid to the base holds or otherwise maintains the top and bottom portions of the base together.

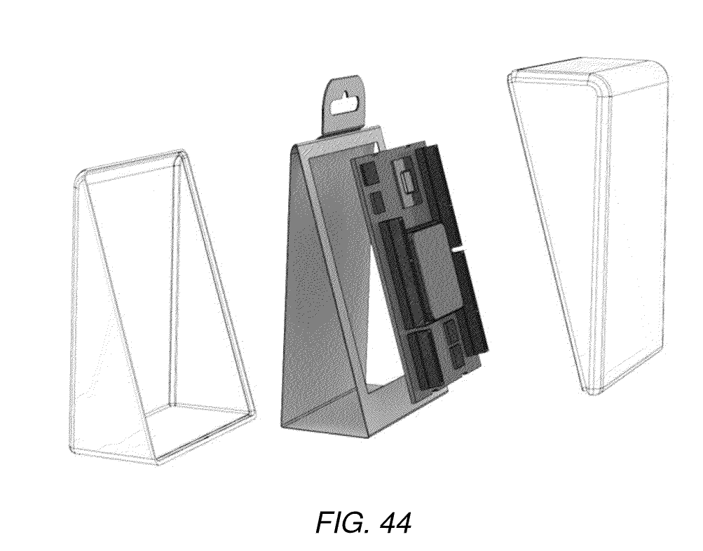

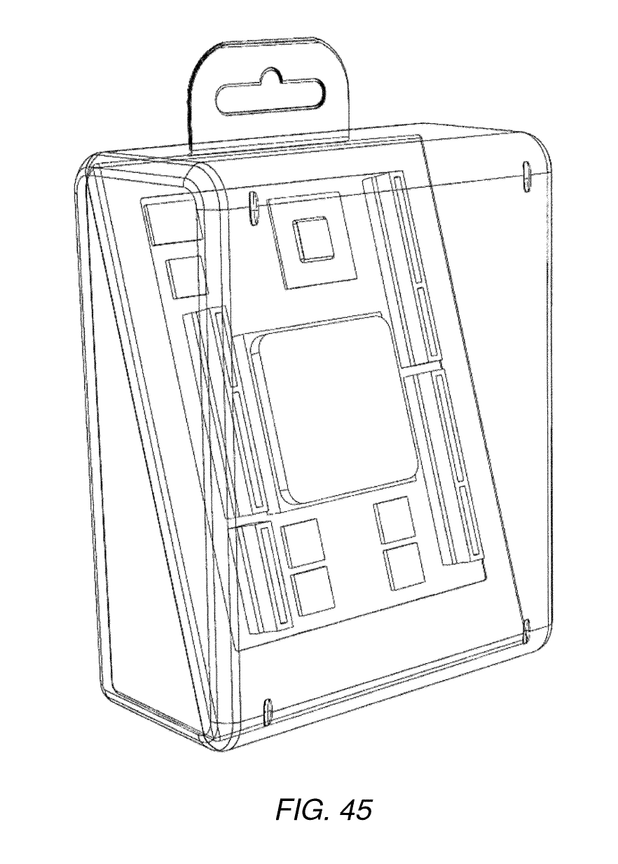

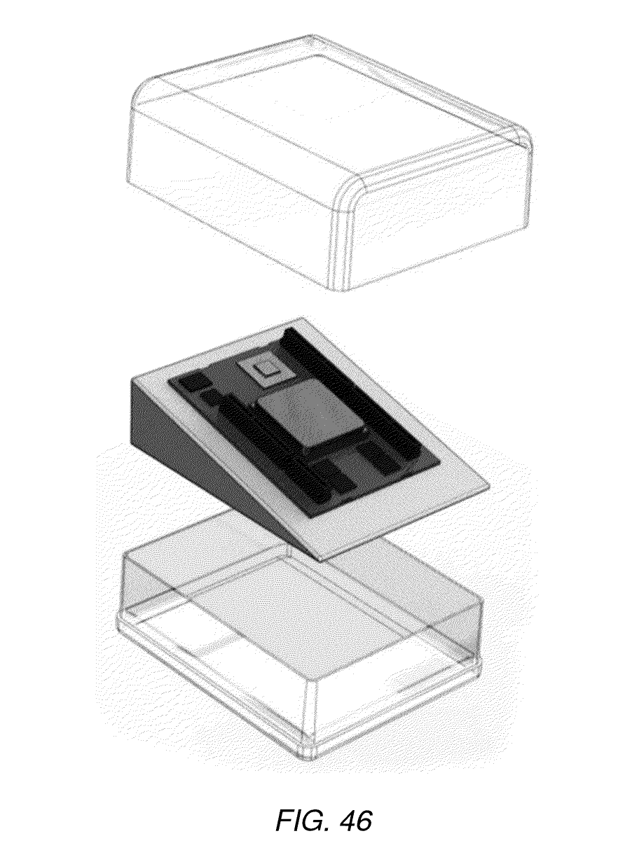

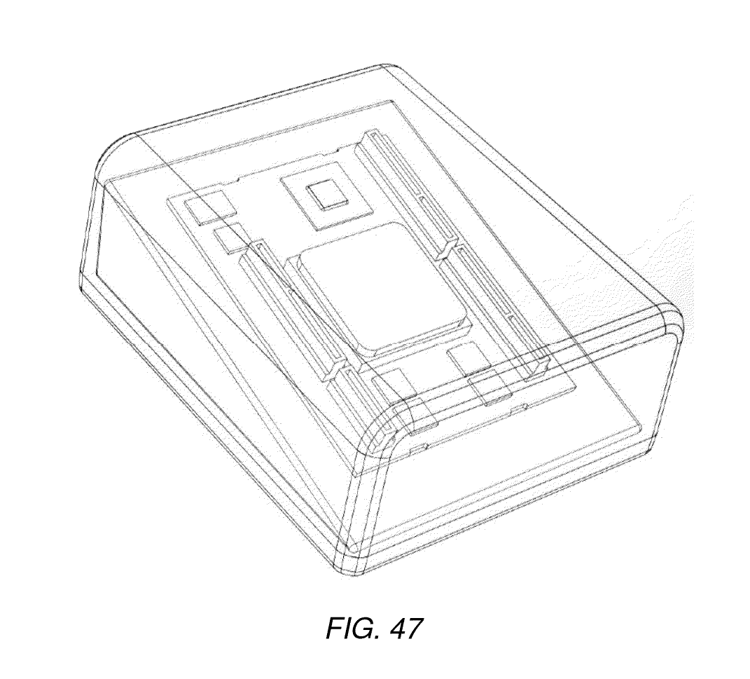

FIGS. 44-47 show various views of modular packaging in accordance with other representative embodiments of the present invention.

In at least some embodiments, one or more surfaces of the top/lid and/or base are formed so as to limit movement of the contents inside of the packaging to increase stability and to further protect the contents. In some embodiments, at least a portion of the top/lid extends toward the contents so as to contact or otherwise reside near the contents to limit the amount of movement that can take place by the clients within the top/lid. In some embodiments, the top/lid includes one or more indents formed to touch or otherwise reside near a surface of the contents. Embodiments of the present invention include one or more indents on any or all of the sides of the top/lid. In some embodiments, the top/lid is molded to the particular configuration of the contents. In some embodiments, at least a portion of the contents is imprinted on at least a portion of the top/lid to provide a location for contents.

In some embodiments, hangers and/or handles are provided. In some embodiments, the hangers and/or handles are formed on an outside surface and/or on an inside surface of the top/lid. In some embodiments, at least a portion of the hangers and/or handles are provided within one or more of the walls and/or top of the top/lid. In some embodiments, the hangers and/or handles allow for the inclusion of anti-theft devices, marketing devices, sales devices, supportive/structural devices, and/or aesthetically pleasing devices.

In some embodiments, a lighting system is incorporated with the packaging to selectively provide illumination. The lighting system includes a power source, such as a battery, solar cell, or other power source and one or more light sources, such as a light emitting diode or other light source. Embodiments embrace the use of one or more colors of light sources. In some embodiments, the illumination is provided based on a timer. In some embodiments, the illumination is provided upon use of a switch. In some embodiments, the illumination is provided upon movement of the modular packaging. In some embodiments, the illumination is provided touching a portion of the modular packaging. In some embodiments, the particular color of illumination identifies one or more the contents or one or more characteristics of the contents that are within the particular modular packaging.

Thus, embodiments of the present invention relate to modular packaging. More particularly, at least some embodiments of the present invention relate to modular packaging of computer systems, devices and components. Embodiments of the invention may be particularly useful with systems and methods described in some of the related applications.

The present invention may be embodied in other specific forms without departing from its spirit or essential characteristics. The described embodiments are to be considered in all respects only as illustrative and not restrictive. The scope of the invention is, therefore, indicated by the appended claims, rather than by the foregoing description. All changes which come within the meaning and range of equivalency of the claims are to be embraced within their scope.

What is claimed and desired to be secured by Letters Patent is:

1. A modular packaging system comprising:
a base having a top portion and a bottom portion, the top portion configured to be selectively coupled to the bottom portion;
a locking device having a plurality of mating protrusions configured to extend through slots in the top portion of the base and into corresponding mating channels of a device; and
one of a plurality of lids selectively coupled to the base, wherein each of the lids allows for a difference volume to be formed between the lid and base.

2. A modular packaging system as recited in claim 1, further comprising a covering configured to selectively contain the lid and base combination.
